(19) United States
(12) Patent Application Publication
(10) Pub. No.: US 2024/0258349 A1
(43) Pub. Date: Aug. 1, 2024

(54) IMAGING ELEMENT

(71) Applicant: SONY SEMICONDUCTOR SOLUTIONS CORPORATION, Kanagawa (JP)

(72) Inventor: Kazuhiro GOI, Kanagawa (JP)

(73) Assignee: SONY SEMICONDUCTOR SOLUTIONS CORPORATION, Kanagawa (JP)

(21) Appl. No.: 18/292,505

(22) PCT Filed: Aug. 18, 2021
(86) PCT No.: PCT/JP2021/030243

§ 371 Date: Jan. 26, 2024

Related U.S. Application Data
(60) Provisional application No. 63/230,369, filed on Aug. 6, 2021.

(51) Int. Cl. H01L 27/146

(52) U.S. Cl. CPC H01L 27/14625; H01L 27/14627; H01L 27/14645

(57) ABSTRACT

Provided is an imaging element according to the present technology including a pixel array that includes pixels that are arranged two-dimensionally and each of which has a photoelectric converter and a spectroscopic element that is arranged on a light incident side of the photoelectric converter and disperses light in a predetermined wavelength range, in which the pixels include cyan pixels that receive cyan light, magenta pixels that receive magenta light, and yellow pixels that receive yellow light.

### TECHNICAL FIELD

The present technology relates to an imaging element provided with a spectroscopic element which disperses light in a predetermined wavelength range in incident light.

### BACKGROUND ART

The imaging element executes photoelectric conversion on the basis of received light to thereby output a pixel signal.

As a technology relating to the imaging element, for example, there is disclosed a technology for using micro-metalenses to achieve high sensitivity in NPL 1.

### CITATION LIST

### Non Patent Literature

NPL 1: M. Miyata, et al., “Color Splitting Micro-metalenses for High-sensitivity Color Image Sensors”, CLEO 2021 FTu2M.5

### SUMMARY

### Technical Problem

In the imaging element, it is required to increase light reception efficiency and to increase color reproducibility.

The present technology has an object to propose a configuration of an imaging element capable of achieving an increase in characteristics of a captured image.

### Solution to Problem

An imaging element according to the present technology includes a pixel array that includes pixels that are arranged two-dimensionally and each of which has a photoelectric converter and a spectroscopic element that is arranged on a light incident side of the photoelectric converter and disperses light in a predetermined wavelength range, in which the pixels include cyan pixels that receive cyan light, magenta pixels that receive magenta light, and yellow pixels that receive yellow light.

Light which is not received by the photoelectric converter of the cyan pixel is only red light of the red light, green light, and blue light. Moreover, light which is not received by the photoelectric converter of the magenta pixel is only the green light, and light which is not received by the photoelectric converter of the yellow pixel is only the blue light. The light in each of these wavelength bands is dispersed to the pixels of the other types.

### BRIEF DESCRIPTION OF DRAWINGS

FIG. 1 is a schematic view of an imaging element in a first embodiment of the present technology.

FIG. 2 is a view for illustrating an arrangement example of pixels.

FIG. 3 is a cross-sectional view for illustrating a configuration example of the pixel.

FIG. 4 is a cross-sectional view parallel with an xz plane for a cyan pixel.

FIG. 5 is a cross-sectional view parallel with a yz plane for the cyan pixel.

FIG. 6 is a view for illustrating a state in which R light dispersed from the cyan pixel is received in peripheral pixels.

FIG. 7 is a cross-sectional view parallel with the xz plane for a magenta pixel.

FIG. 8 is a cross-sectional view parallel with the yz plane for the magenta pixel.

FIG. 9 is a cross-sectional view parallel with a line x =y and a z axis for the magenta pixel.

FIG. 10 is a view for illustrating a state in which G light dispersed from the magenta pixel is received in peripheral pixels.

FIG. 11 is a cross-sectional view parallel with the xz plane for a yellow pixel.

FIG. 12 is a cross-sectional view parallel with the line x=y and the z axis for the yellow pixel.

FIG. 13 is a view for illustrating a state in which B light dispersed from the yellow pixel is received in peripheral pixels.

FIG. 14 is a cross-sectional view parallel with the xz plane for a green pixel.

FIG. 15 is a cross-sectional view parallel with the yz plane for the green pixel.

FIG. 16 is a cross-sectional view parallel with the line x=y and the z axis for the green pixel.

FIG. 17 is a view for illustrating a state in which the R light and the B light dispersed from the green pixel are received in peripheral pixels.

FIG. 18 is a view for illustrating a configuration example of a spectroscopic element.

FIG. 19 is a view for illustrating a case in which light is made incident to only a pixel adjacent in a diagonal direction.

FIG. 20 is a view for illustrating a case in which a propagation direction of the light dispersed in the diagonal direction is brought closer to an x-axis direction.

FIG. 21 is a view for illustrating an example of a pixel block provided for an imaging element in a second embodiment.

FIG. 22 is a view for illustrating a state in which the R light incident to the pixel block is dispersed and is received by peripheral pixels.

FIG. 23 is a view for illustrating a state in which the G light incident to the pixel block is dispersed and is received by the green pixel.

FIG. 24 is a view for illustrating a state in which the B light incident to the pixel block is dispersed and is received by peripheral pixels.

FIG. 25 is a view for illustrating another example of the pixel arrangement in the pixel block.

FIG. 26 is a view for illustrating an example of an imaging element in a third embodiment.

FIG. 27 is a view for illustrating a state in which the R light dispersed from the cyan pixel is received in the peripheral magenta pixels and yellow pixels.

FIG. 28 is a view for illustrating a state in which the G light dispersed from the magenta pixel is received in the peripheral cyan pixels and yellow pixels.

FIG. 29 is a view for illustrating a state in which the B light dispersed from the yellow pixel is received in the peripheral cyan pixels and magenta pixels.

FIG. 30 is a view for illustrating a configuration example of the spectroscopic element in the third embodiment.

FIG. 31 is a cross-sectional view for illustrating a configuration example of the pixel in a fourth embodiment.

FIG. 32 is a graph for illustrating a transmission spectrum of a color splitter provided for the green pixel.

FIG. 33 is an exploded perspective view of the green pixel.

FIG. 34 is a view for illustrating four photoelectric converters provided for each pixel.

FIG. 35 is a view for illustrating disperse dictions of each pixel.

FIG. 36 is a view for illustrating a configuration example in which a part of the green pixels has a function of detecting a phase difference in the x-axis direction.

FIG. 37 is a view for illustrating another example of the pixel arrangement having the function of detecting the phase difference in the x-axis direction.

FIG. 38 is a view for illustrating still another example of the pixel arrangement having the function of detecting the phase difference in the x-axis direction.

FIG. 39 is a cross-sectional view for illustrating a configuration of pixels provided for an imaging element in a fifth embodiment.

FIG. 40 is a view for illustrating a modification example in which each imaging element is provided with an on-chip microlens in each embodiment.

FIG. 41 is a view for illustrating a modification example in which microstructures are formed on a surface of a transparent layer.

FIG. 42 is a view for illustrating a modification example of the configuration in which six pixels are adjacent to one pixel.

FIG. 43 is a view for illustrating another modification example of the configuration in which six pixels are adjacent to one pixel.

FIG. 44 is a view for illustrating an example of a pixel array including three pixels which receive light in the same wavelength band as one block.

FIG. 45 is a view for illustrating a modification example in which a color filter is provided to each pixel.

### DESCRIPTION OF EMBODIMENTS

Embodiments are now described in the following order with reference to the accompanying drawings.
<1. Configuration of Imaging Element>
<2. Configuration of Spectroscopic Element>
<3. Summary of First Embodiment>
<4. Second Embodiment>
<5. Third Embodiment>
<6. Fourth Embodiment
<7. Fifth Embodiment>
<8. Modification Examples>
<9. Summary>
<10. Present Technology>

### 1. Configuration of Imaging Element

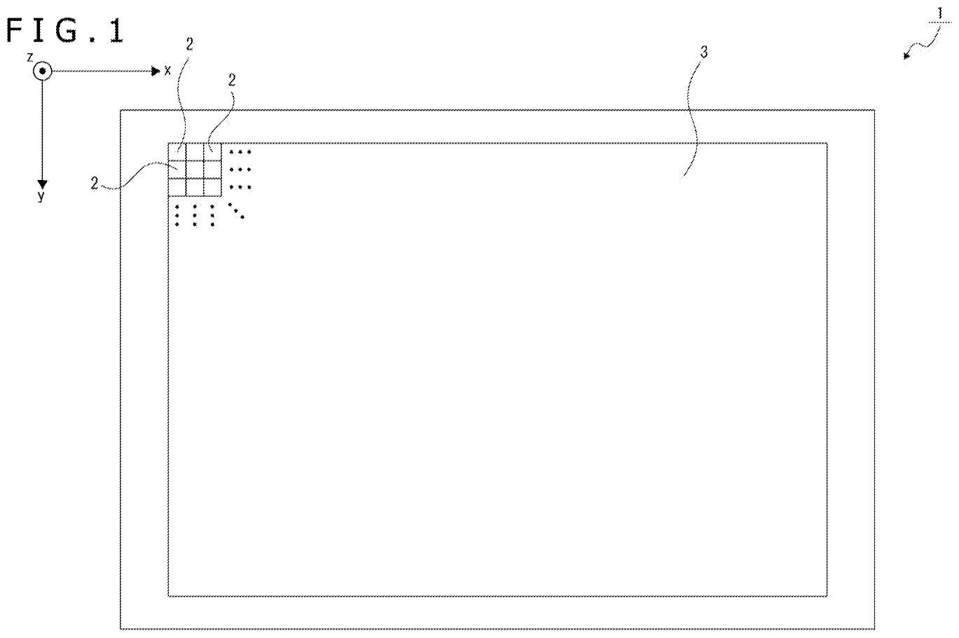

A configuration of an imaging element 1 according to the first embodiment is illustrated in FIG. 1.

The imaging element 1 includes a pixel array 3 in which pixels 2 are two-dimensionally arranged.

In the following description, a lengthwise direction of the pixel array 3 is set to an x-axis direction, and a widthwise direction of the pixel array 3 is set to a y-axis direction. Moreover, a thickness direction of the pixel array 3 is set to a z-axis direction. The pixels 2 are arranged along the x-axis direction and the y-axis direction.

The imaging element 1 is provided with a plurality of types of pixels 2 different in wavelength band of received light from one another. The pixel 2 has a rectangular shape as viewed from an incident side of the light, and a square shape is employed as an example of the rectangular shape in this example. In the following example, the imaging element 1 is provided with cyan pixels Cy which receive G (green) light and B (blue) light, magenta pixels Mg which receive R (red) light and the B (blue) light, yellow pixels Ye which receive the R (red) light and the G (green) light, and green pixels G which receive the G (green) light.

Note that this configuration is only an example.

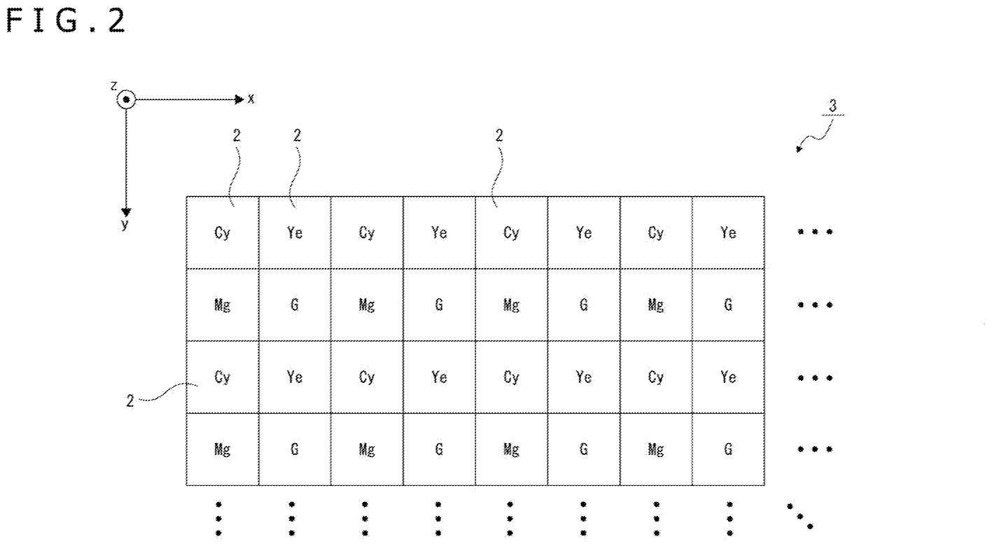

An arrangement example of the cyan pixels Cy, the magenta pixels Mg, the yellow pixels Ye, and the green pixels G are illustrated in FIG. 2.

As illustrated, an adjacent pixel of the cyan pixel Cy in the x-axis direction is the yellow pixel Ye, and an adjacent pixel of the cyan pixel Cy in the y-axis direction is the magenta pixel Mg.

Moreover, a pixel positioned in a diagonal direction of the cyan pixel Cy is the green pixel G.

The pixel array 3 is formed by arranging 2×2 blocks each including one cyan pixel Cy, one magenta pixel Mg, one yellow pixel Ye, and one green pixel G in the x-axis direction and the y-axis direction.

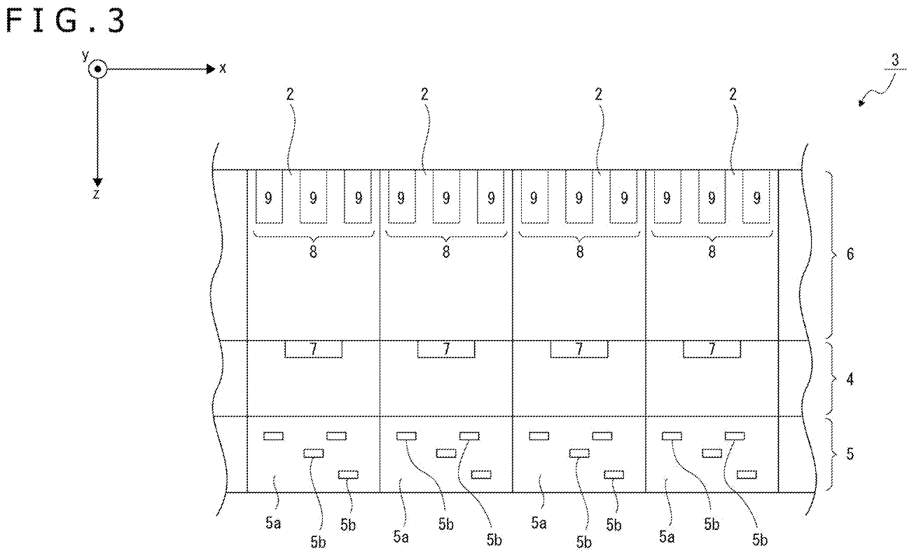

A configuration example of the pixel 2 is illustrated in FIG. 3.

The pixel 2 is constructed by forming a wiring layer 5 formed on a surface side (for example, a first surface side) opposite from a light incident surface of a semiconductor substrate 4 and a transparent layer 6 formed on the light incident surface side (for example, a second surface side) in a layered manner.

The semiconductor substrate 4 includes, for example, the silicon (Si) having a thickness of, for example, approximately 1 μm to 6 μm. Inside the semiconductor substrate 4, a photodiode serving as a photoelectric converter 7 is formed in a substantially center portion on an xy plane of the pixel 2.

In a description given hereinafter, the photoelectric converter 7 provided to the cyan pixel Cy is referred to as a photoelectric converter 7c, the photoelectric converter 7 provided to the magenta pixel Mg is referred to as a photoelectric converter 7m, the photoelectric converter 7 provided to the yellow pixel Ye is referred to as a photoelectric converter 7y, and the photoelectric converter 7 provided to the green pixel G is referred to as a photoelectric converter 7g.

The wiring layer 5 includes wires 5b stacked as a plurality of layers in the z-axis direction inside an insulating section 5a including an insulating material.

The wires 5b arranged in layers different from each other are appropriately electrically connected to each other via through-hole via or the like, not illustrated.

The transparent layer 6 includes an organic material such as a transparent resin or an inorganic material such as silicon oxide, but the material of the transparent layer 6 is not limited thereto. Inside the transparent layer 6, a spectroscopic element 8 is formed.

The spectroscopic element (color splitter) 8 includes a combination of a plurality of microstructures 9.

The number of microstructures 9 forming one spectroscopic element 8 may be any number. In an example described hereinafter, a description is given of an example in which nine microstructures 9 are combined to form one spectroscopic element 8.

The spectroscopic element 8 has different in configuration among the cyan pixel Cy, the magenta pixel Mg, the yellow pixel Ye, and the green pixel G. In a description given hereinafter, the spectroscopic element 8 provided to the cyan pixel Cy is referred to as a spectroscopic element 8c, the spectroscopic element 8 provided to the magenta pixel Mg is referred to as a spectroscopic element 8m, the spectroscopic element 8 provided to the yellow pixel Ye is referred to as a spectroscopic element 8y, and the spectroscopic element 8 provided to the green pixel G is referred to as a spectroscopic element 8g.

Note that, in FIG. 3, the semiconductor substrate 4, the insulating section 5a, and the transparent layer 6 are illustrated so as to be partitioned for each pixel 2, but this representation is for convenience of description. The semiconductor substrate 4, the insulating section 5a, and the transparent layer 6 may be formed across a plurality of pixels 2 and are not required to be partitioned for each pixel 2. This similarly applies to each of the following drawings.

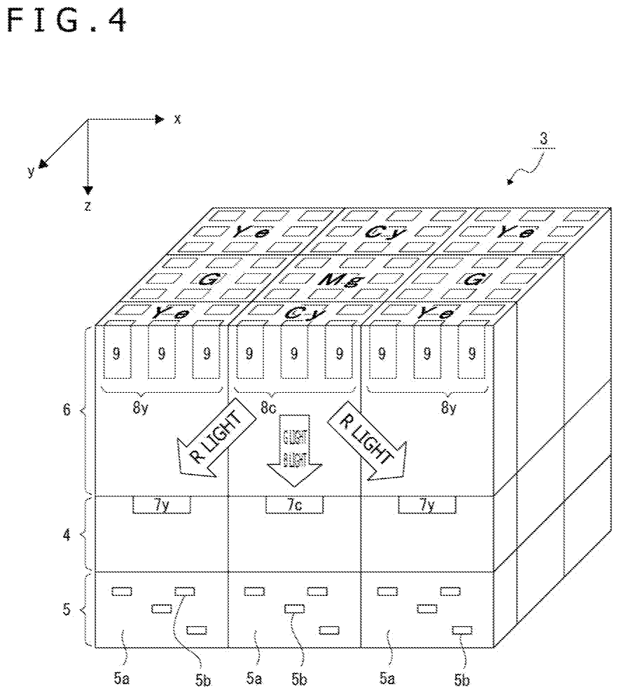

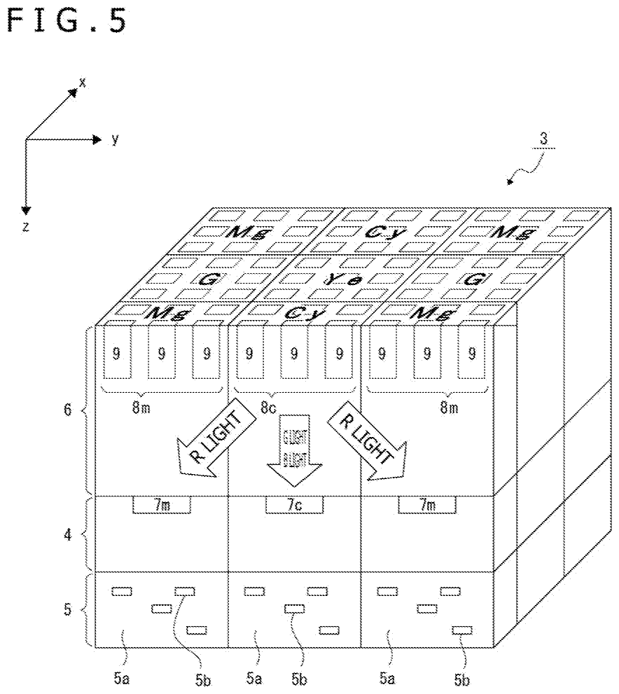

For the cyan pixel Cy, a cross-sectional view parallel with an xz plane is illustrated in FIG. 4, and a cross-sectional view parallel with a yz plane is illustrated in FIG. 5.

As illustrated in FIG. 4 and FIG. 5, the spectroscopic element 8c provided to the cyan pixel Cy disperses the R light from the incident light and makes the R light incident to the photoelectric converter 7y of the adjacent yellow pixel Ye and the photoelectric converter 7m of the adjacent magenta pixel Mg.

That is, the spectroscopic element 8c causes the G light and the B light to travel straight and to be received by the photoelectric converter 7c and deflects a propagation direction of the R light such that the R light is made incident to the adjacent pixels 2 in the x-axis direction and the y-axis direction.

Note that the spectroscopic element 8c executes the dispersion of the R light such that the R light does not enter the green pixels G diagonally positioned with respect to the cyan pixel Cy on the xy plane.

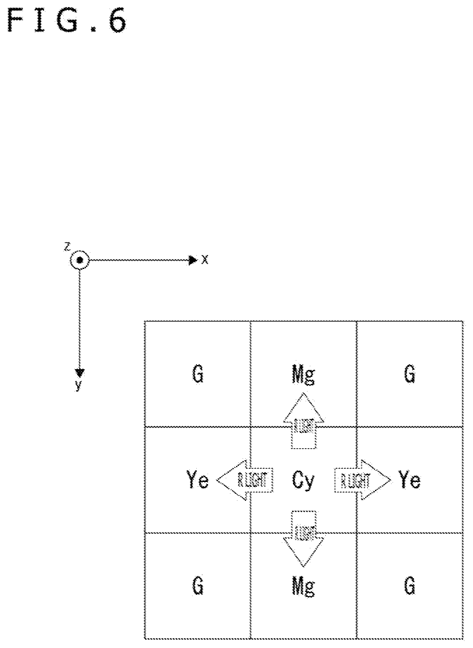

Specifically, as illustrated in FIG. 6, the spectroscopic element 8c executes the dispersion such that the R light is incident to only the adjacent pixels 2 in the x-axis direction and the adjacent pixels 2 in the y-axis direction.

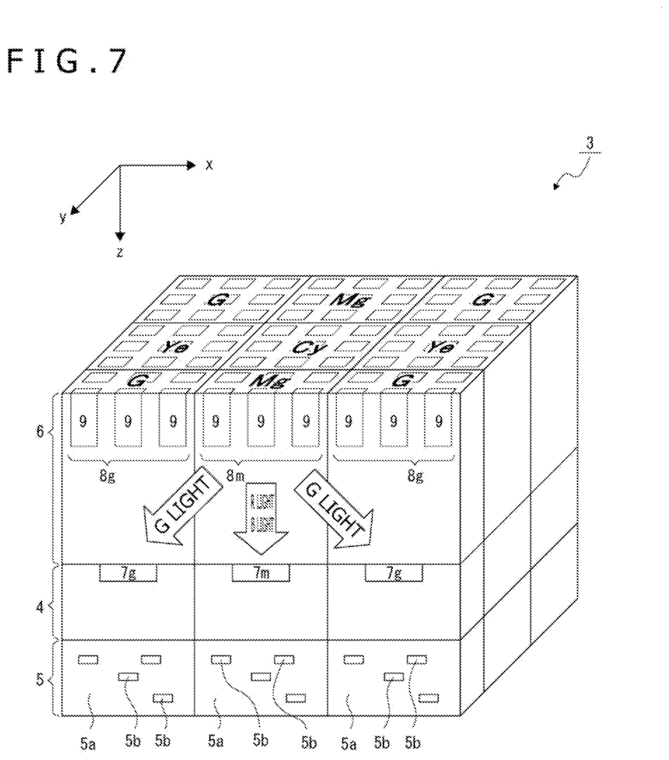

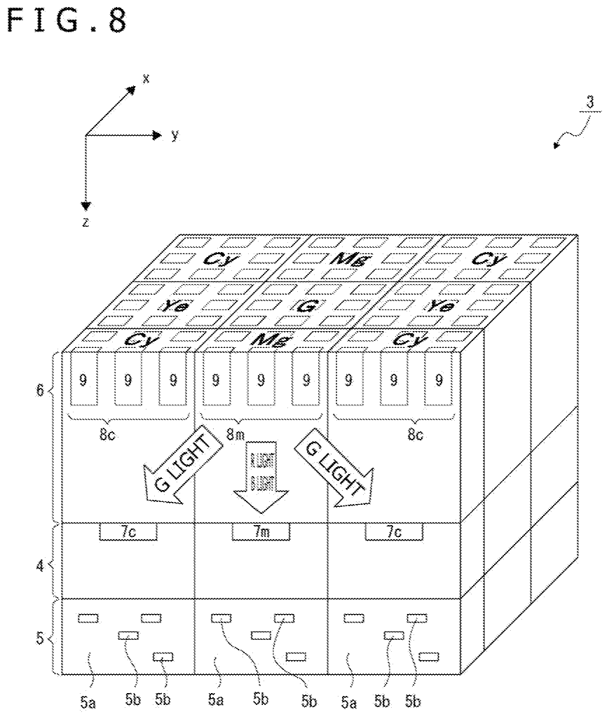

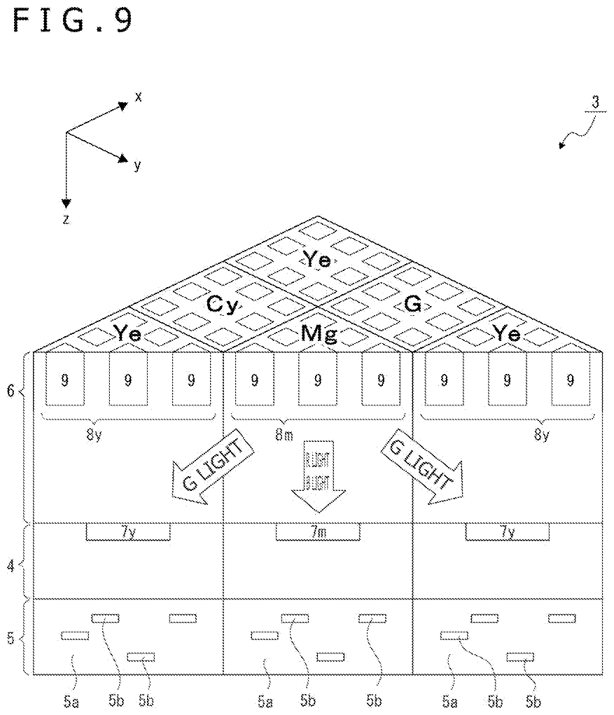

For the magenta pixel Mg, a cross-sectional view parallel with the xz plane is illustrated in FIG. 7, a cross-sectional view parallel with the yz plane is illustrated in FIG. 8, and a cross-sectional view on a plane parallel with a line given by y =x and parallel with the z axis is illustrated in FIG. 9.

As illustrated in FIG. 7, the spectroscopic element 8m provided to the magenta pixel Mg makes a part of the G light which is dispersed from the incident light, incident to the photoelectric converters 7g of the green pixels G adjacent in the x-axis direction.

Moreover, as illustrated in FIG. 8, the spectroscopic element 8m makes a part the G light which is dispersed from the incident light, incident to the photoelectric converters 7c of the cyan pixels Cy adjacent in the y-axis direction.

Further, as illustrated in FIG. 9, the spectroscopic element 8m makes a part of the G light which is dispersed from the incident light, incident to the photoelectric converters 7y of the yellow pixels Ye positioned in the diagonal directions on the xy plane.

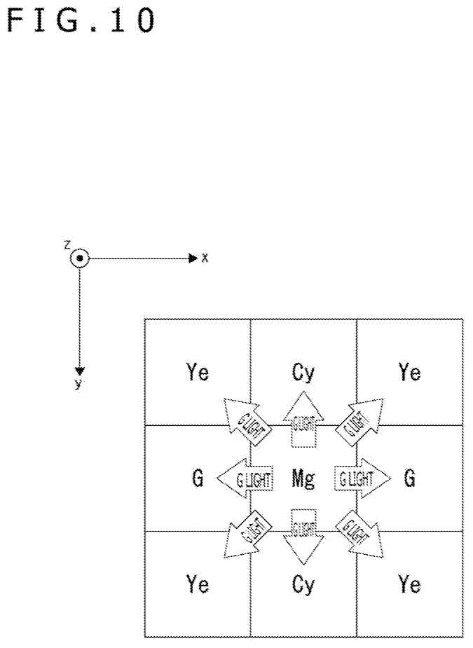

That is, the spectroscopic element 8m causes the R light and the B light to travel straight, thereby causing the photoelectric converter 7m to receive the R light and the B light and deflects a propagation direction of the G light such that the G light is incident to the adjacent pixels 2 in the x-axis direction and the y-axis direction and the pixels 2 positioned in the diagonal directions on the xy plane (see FIG. 10).

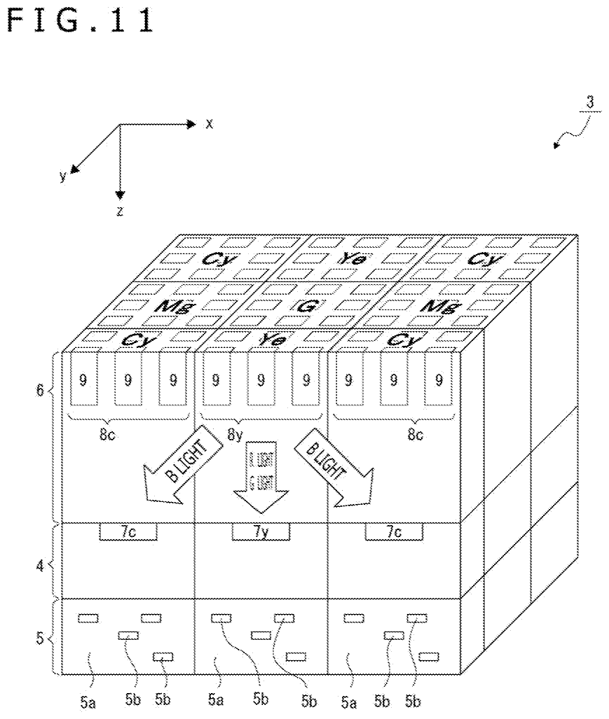

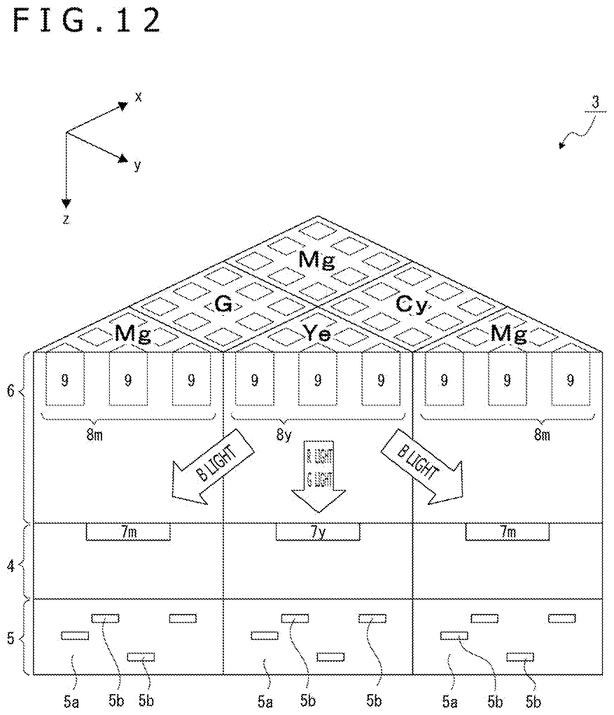

For the yellow pixel Ye, a cross-sectional view parallel with the xz plane is illustrated in FIG. 11, and a cross-sectional view on a plane parallel with the line given by y=x and parallel with the z axis is illustrated in FIG. 12.

As illustrated in FIG. 11, the spectroscopic element 8y provided to the yellow pixel Ye makes a part of the B light which is dispersed from the incident light, incident to the photoelectric converters 7c of the cyan pixels Cy adjacent in the x-axis direction.

Moreover, as illustrated in FIG. 12, the spectroscopic element 8y makes a part of the B light which is dispersed from the incident light, incident to the photoelectric converters 7m of the magenta pixels Mg positioned in the diagonal directions on the xy plane.

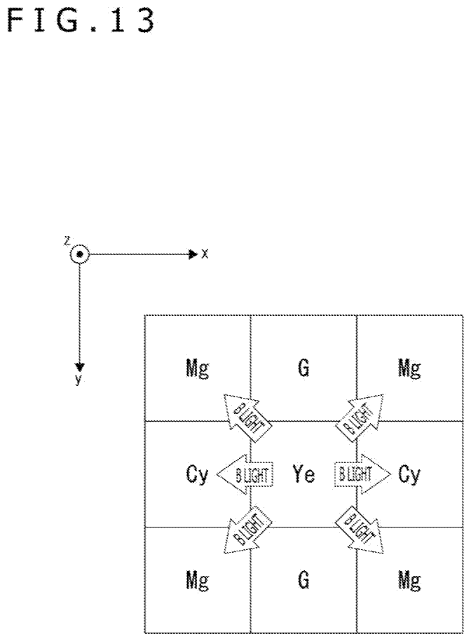

That is, the spectroscopic element 8y causes the R light and the G light to travel straight, thereby causing the photoelectric converter 7y to receive the R light and the G light and deflects a propagation direction of the B light such that the B light is incident to the adjacent pixels 2 in the x-axis direction and the pixels 2 positioned in the diagonal directions on the xy plane (see FIG. 13).

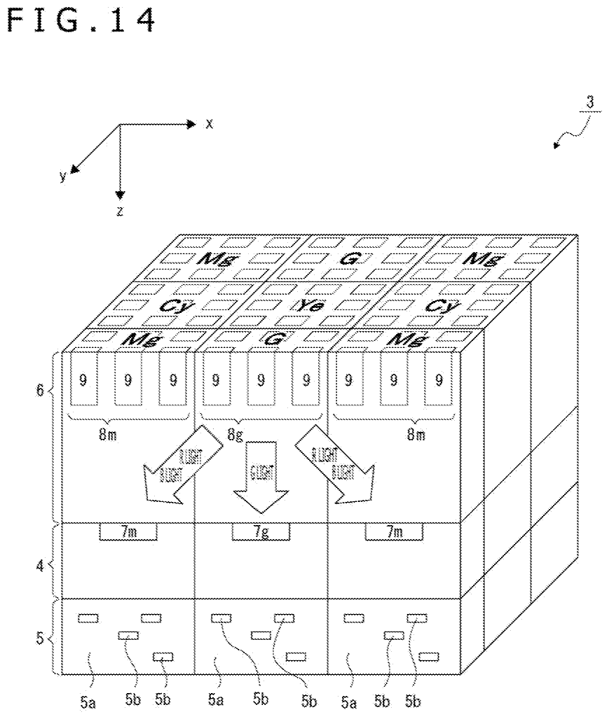

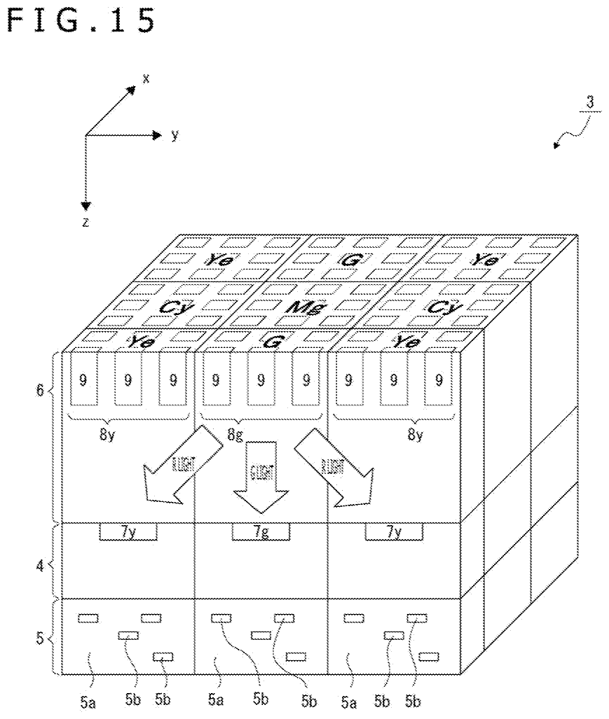

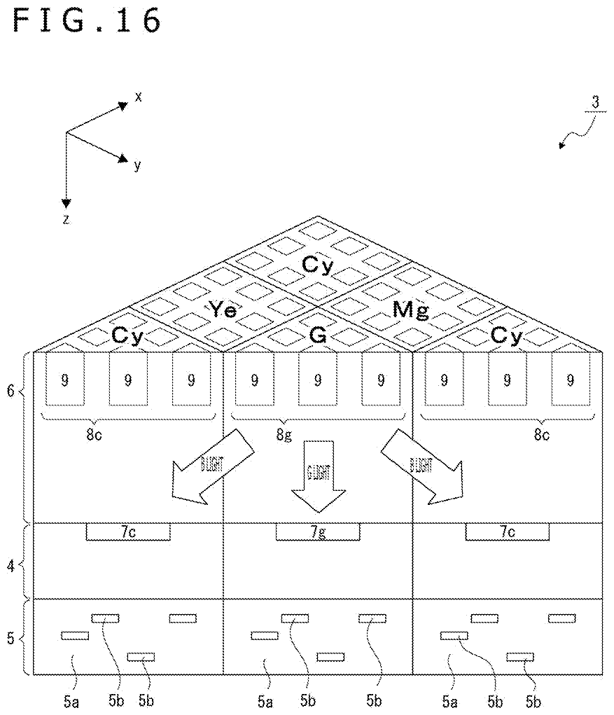

Finally, for the green pixel G, a cross-sectional view parallel with the xz plane is illustrated in FIG. 14, a cross-sectional view parallel with the yz plane is illustrated in FIG. 15, and a cross-sectional view on a plane parallel with the line given by y=x and parallel with the z axis is illustrated in FIG. 16.

As illustrated in FIG. 14, the spectroscopic element 8g provided to the green pixel G makes a part of the R light and a part of the B light which are dispersed from the incident light, incident to the photoelectric converters 7m of the magenta pixels Mg adjacent in the x-axis direction.

Moreover, as illustrated in FIG. 15, the spectroscopic element 8g makes a part the R light which is dispersed from the incident light, incident to the photoelectric converters 7y of the yellow pixels Ye adjacent in the y-axis direction.

Further, as illustrated in FIG. 16, the spectroscopic element 8g makes a part of the B light which is dispersed from the incident light, incident to the photoelectric converters 7c of the cyan pixels Cy positioned in the diagonal directions on the xy plane.

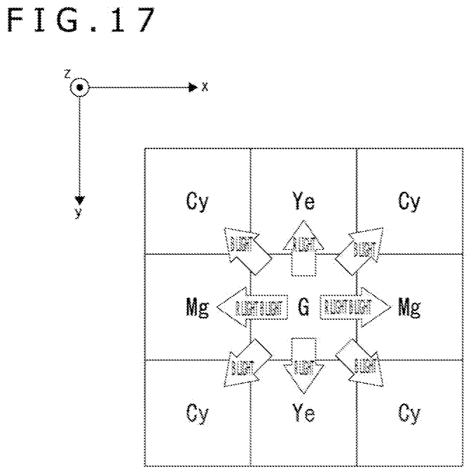

That is, the spectroscopic element 8g causes the G light to travel straight, thereby causing the photoelectric converter 7g to receive the G light and deflects propagation directions of the R light and the B light such that at least one of the R light and the B light is incident to either one of or each of the adjacent pixels 2 in the x-axis direction and the y-axis direction and the pixels 2 positioned in the diagonal directions on the xy plane (see FIG. 17).

Note that, as appreciated from the description given above, the spectroscopic element 8 is configured such that the light in the specific wavelength band is not made incident to the photoelectric converter 7 positioned directly below (z-axis direction), and hence the spectroscopic element 8 has a function of a color filter.

### 2. Configuration of Spectroscopic Element

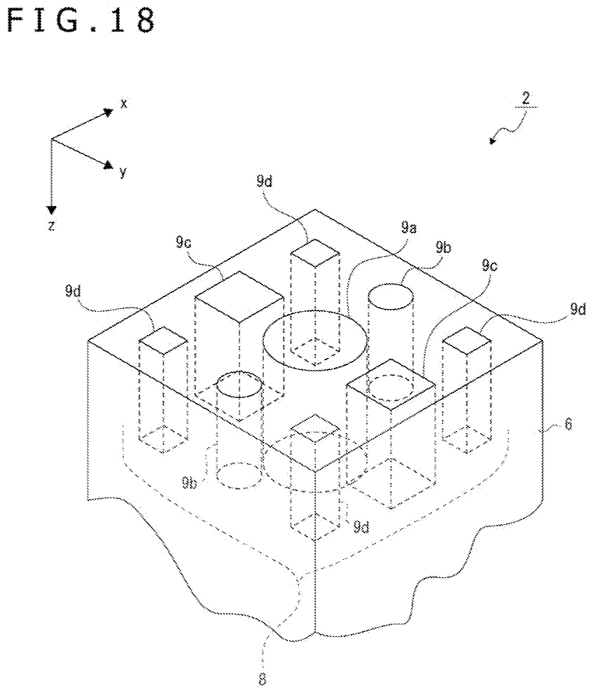

As described above, the spectroscopic element 8 includes the plurality of types of microstructures 9. An arrangement example of the microstructures 9 is illustrated in FIG. 18.

FIG. 18 illustrates an end surface of the transparent layer 6 on the light incident side. As illustrated, there are provided one first microstructure 9a arranged in a substantially center portion on the xy plane of the pixel 2, two second microstructures 9b, two third microstructures 9c, and four fourth microstructures 9d.

The second microstructures 9b are provided apart from the first microstructure 9a in the x-axis direction.

The third microstructures 9c are provided apart from the first microstructure 9a in the y-axis direction.

The fourth microstructures 9d are provided apart from the first microstructure 9a in the diagonal directions on the xy plane.

For example, in a case in which the third microstructure 9c is configured such that the phase of the R light lags with respect to the first microstructure 9a and the fourth microstructure 9d is configured such that the phase of the R light lags with respect to the second microstructure 9b, the R light does not enter the photoelectric converter 7 positioned directly below the pixel 2 and enters the photoelectric converters 7 of the pixels 2 adjacent in the y-axis direction. As a result, for example, the R light made incident to the cyan pixel Cy is made incident to the yellow pixels Ye adjacent in the x-axis direction.

Moreover, in a case in which the phase of the B light passing through the second microstructure 9b, the third microstructure 9c, and the fourth microstructure 9d does not change with respect to the B light passing through the first microstructure 9a, the B light incident to the pixel 2 is made incident to the photoelectric converter 7 positioned directly below. As a result, for example, the B light incident to the cyan pixel Cy is incident to the photoelectric converter 7c positioned directly below the cyan pixel Cy.

Note that, in a case in which the phase of the B light passing through the second microstructure 9b, the third microstructure 9c, and the fourth microstructure 9d leads with respect to the B light passing through the first microstructure 9a, a light-collecting effect for the photoelectric converter 7 positioned directly below can be obtained.

The refractive index of the microstructure 9 is set for each of the R light, the G light, and the B light so as to be dispersed to the predetermined direction.

The refractive index of the microstructure 9 is appropriately set according to the shape, the thickness, the length, the material, and the like.

Note that the spectroscopic element 8 may include a combination of the three types of microstructure 9 depending on the direction to deflect the light in each wavelength band. For example, the second microstructure 9b and the third microstructure 9c may be the same.

### 3. Summary of First Embodiment

As illustrated in FIG. 6, the R light incident to the cyan pixel Cy is made incident to the magenta pixels Mg and the yellow pixels Ye adjacent to the cyan pixel Cy in the x-axis direction and the y-axis direction.

As illustrated in FIG. 10, the G light incident to the magenta pixel Mg is made incident to the cyan pixels Cy, the yellow pixels Ye, and the green pixels G adjacent to the magenta pixel Mg in the x-axis direction, the y-axis direction, and the diagonal directions.

As illustrated in FIG. 13, the B light incident to the yellow pixel Ye is made incident to the cyan pixels Cy adjacent to the yellow pixel Ye in the x-axis direction and the magenta pixels Mg adjacent in the diagonal directions.

As illustrated in FIG. 17, the R light incident to the green pixel G is made incident to the magenta pixels Mg and the yellow pixels Ye adjacent to the green pixel G in the x-axis direction and the y-axis direction.

As illustrated in FIG. 17, the B light incident to the green pixel G is made incident to the magenta pixels Mg adjacent to the green pixel G in the x-axis direction and the cyan pixels Cy adjacent in the diagonal directions.

That is, there is not such a case in which the light in each wavelength band incident to each pixel 2 is dispersed to only the pixels 2 adjacent diagonally.

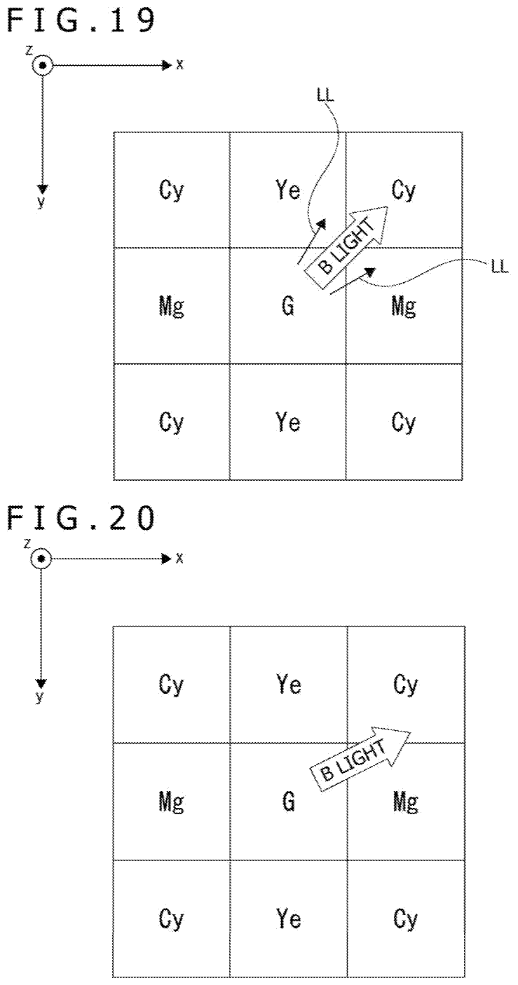

The case in which the dispersion is executed such that the incidence to only the pixels 2 adjacent diagonally occurs is now considered. For example, in a case in which the B light incident to the green pixel G is made incident to only the cyan pixels Cy adjacent in the diagonal directions, leakage light LL to the magenta pixel Mg and the yellow pixel Ye adjacent in the x-axis direction and the y-axis direction, respectively, highly possibly occurs as illustrated in FIG. 19.

However, with this configuration, in a case in which the dispersed light is made incident to the other pixels 2 adjacent in the diagonal directions, the dispersed light is also made incident to any pixels 2 adjacent in the x-axis direction or the y-axis direction.

That is, the B light incident to the green pixel G is made incident to not only the cyan pixels Cy adjacent in the diagonal directions, but also the magenta pixels Mg adjacent in the x-axis direction.

Thus, as illustrated in FIG. 20, by configuring the spectroscopic element 8 such that the B light incident to the green pixel G propagates toward the magenta pixel Mg, that is, the B light is dispersed such that an angle formed between the propagation direction of the B light and the x axis is small, the incidence of the leakage light LL to the yellow pixel Ye adjacent in the y-axis direction can be suppressed.

As a result, an increase in characteristics by the dispersion can be achieved.

### 4. Second Embodiment

An imaging element 1A in a second embodiment treats four pixels including two pixels arranged in each of the x-axis direction and the y-axis direction as one pixel block 10 and executes the dispersion such that the light incident to one pixel block 10 is not received by other pixel blocks 10.

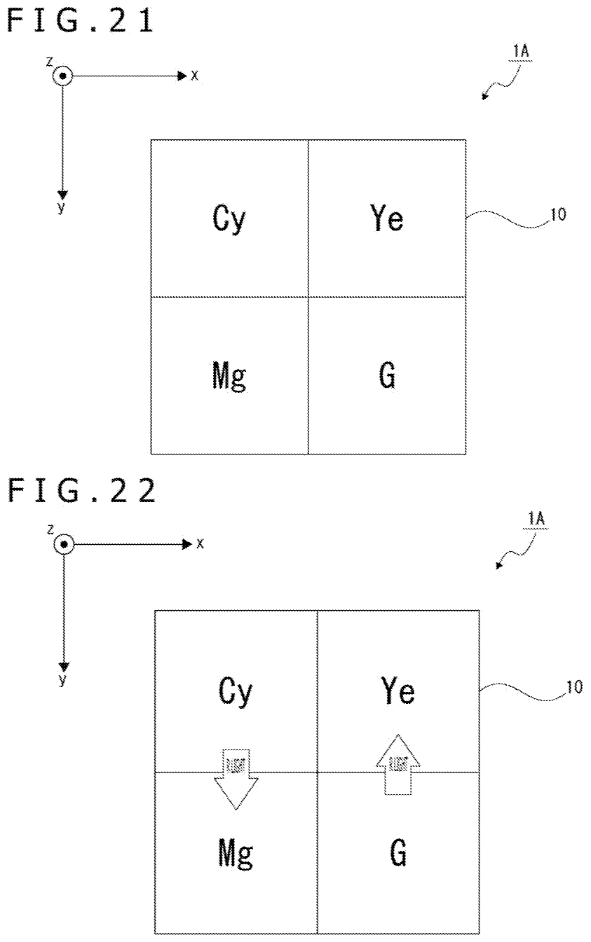

An example of the pixel block 10 is illustrated in FIG. 21.

The pixel block 10 includes each one of the cyan pixel Cy, the magenta pixel Mg, the yellow pixel Ye, and the green pixel G.

The pixel block 10 is configured such that the cyan pixel Cy and the yellow pixel Ye are adjacent to each other in the x-axis direction and the magenta pixel Mg and the green pixel G are adjacent to each other in the x-axis direction.

Moreover, the pixel block 10 is configured such that the cyan pixel Cy and the magenta pixel Mg are adjacent to each other in the y-axis direction and the yellow pixel Ye and the green pixel G are adjacent to each other in the y-axis direction.

The R light incident to the pixel block 10 is dispersed in the cyan pixel Cy and the green pixel G. Specifically, as illustrated in FIG. 22, the R light incident to the cyan pixel Cy is dispersed toward the magenta pixel Mg adjacent in the y-axis direction. Moreover, the R light incident to the green pixel G is dispersed toward the yellow pixel Ye adjacent in the y-axis direction.

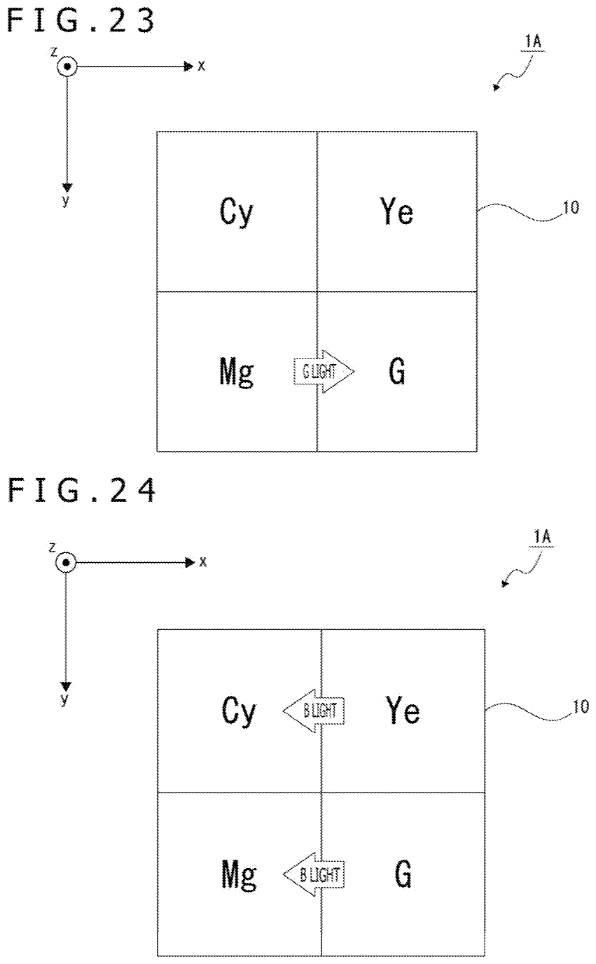

The G light incident to the pixel block 10 is dispersed in the magenta pixel Mg. Specifically, as illustrated in FIG. 23, the G light incident to the magenta pixel Mg is dispersed toward the green pixel G adjacent in the x-axis direction.

The B light incident to the pixel block 10 is dispersed in the yellow pixel Ye and the green pixel G. Specifically, as illustrated in FIG. 24, the B light incident to the yellow pixel Ye is dispersed toward the cyan pixel Cy adjacent in the x-axis direction. Moreover, the B light incident to the green pixel G is dispersed toward the magenta pixel Mg adjacent in the x-axis direction.

As appreciated from FIG. 22, FIG. 23, and FIG. 24, in the pixel block 10 in the present embodiment, there may not be provided the configuration for the dispersion toward the adjacent pixel 2 positioned in the diagonal direction on the xy plane.

Moreover, in the cyan pixel Cy, the magenta pixel Mg, and the yellow pixel Ye, it is only required to disperse light in one wavelength band of the R light, the G light, and the B light toward the one direction.

Moreover, in the green pixel G, it is required to disperse light in two wavelength bands of the R light, the G light, and the B light, but it is only required to direct a dispersion direction thereof toward the pixel 2 adjacent in the x-axis direction or the y-axis direction.

Thus, constraint on design of the spectroscopic element 8 can be reduced, hence, a degree of freedom of the design can be increased, and the dispersion characteristics (filter characteristics) of the spectroscopic element 8 in the intended wavelength band can be increased.

Moreover, the arrangement of the microstructures 9 provided to the spectroscopic element 8 can be simplified and hence, a cost reduction can be achieved. Further, also in such a point that conditions for a material, a shape, a size, and the like for the microstructure 9 can be relaxed, an increase in degree of freedom of design and a reduction in cost can be achieved.

Note that the arrangement mode of the pixels 2 illustrated in FIG. 21 is an example and similar effect can be obtained even in another arrangement mode.

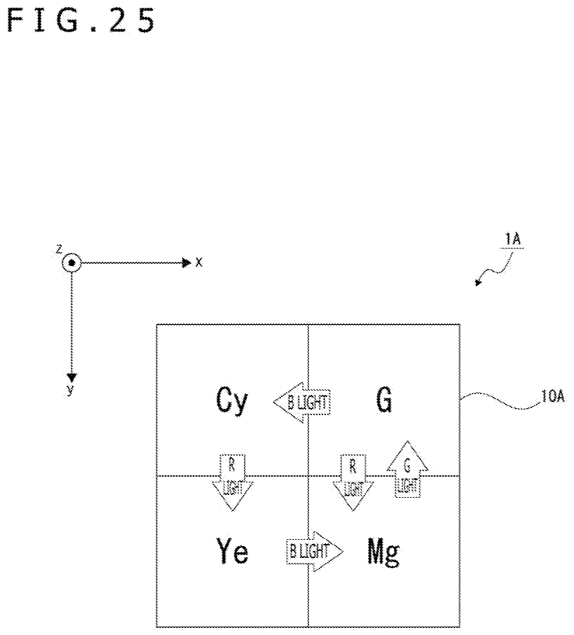

An example is illustrated in FIG. 25.

A pixel block 10A is configured such that the cyan pixel Cy and the green pixel G are adjacent to each other in the x-axis direction and the yellow pixel Ye and the magenta pixel Mg are adjacent to each other in the x-axis direction.

Moreover, the pixel block 10A is configured such that the cyan pixel Cy and the yellow pixel Ye are adjacent to each other in the y-axis direction and the green pixel G and the magenta pixel Mg are adjacent to each other in the y-axis direction.

At this time, the R light incident to the cyan pixel Cy is dispersed toward the yellow pixel Ye, and the R light incident to the green pixel G is dispersed toward the magenta pixel Mg.

Moreover, the G light incident to the magenta pixel Mg is dispersed toward the green pixel G.

Further, the B light incident to the yellow pixel Ye is dispersed toward the magenta pixel Mg, and the B light incident to the green pixel G is dispersed toward the cyan pixel Cy.

Note that a form of selecting toward which pixel 2 the dispersed light is caused to propagate is not limited to this configuration.

Specifically, it is only required that the R light incident to the cyan pixel Cy is dispersed toward the pixel 2 adjacent in either one of the x-axis direction and the y-axis direction of the yellow pixel Ye and the magenta pixel Mg. Moreover, this similarly applies to the R light incident to the green pixel G.

Similarly, it is only required that the G light incident to the magenta pixel Mg is dispersed toward the pixel 2 adjacent in either one of the x-axis direction and the y-axis direction of the cyan pixel Cy, the yellow pixel Ye, and the green pixel G.

Further, it is only required that the B light incident to the yellow pixel Ye is dispersed toward the pixel 2 adjacent in either one of the x-axis direction and the y-axis direction of the cyan pixel Cy and the magenta pixel Mg. Moreover, this similarly applies to the B light incident to the green pixel G.

### 5. Third Embodiment

In an imaging element 1B in a third embodiment, the shape of each pixel 2 has a hexagonal shape as viewed from the light incident side.

Moreover, as the pixels 2, the cyan pixel Cy, the magenta pixel Mg, and the yellow pixel Ye are provided, and the green pixel G is not provided.

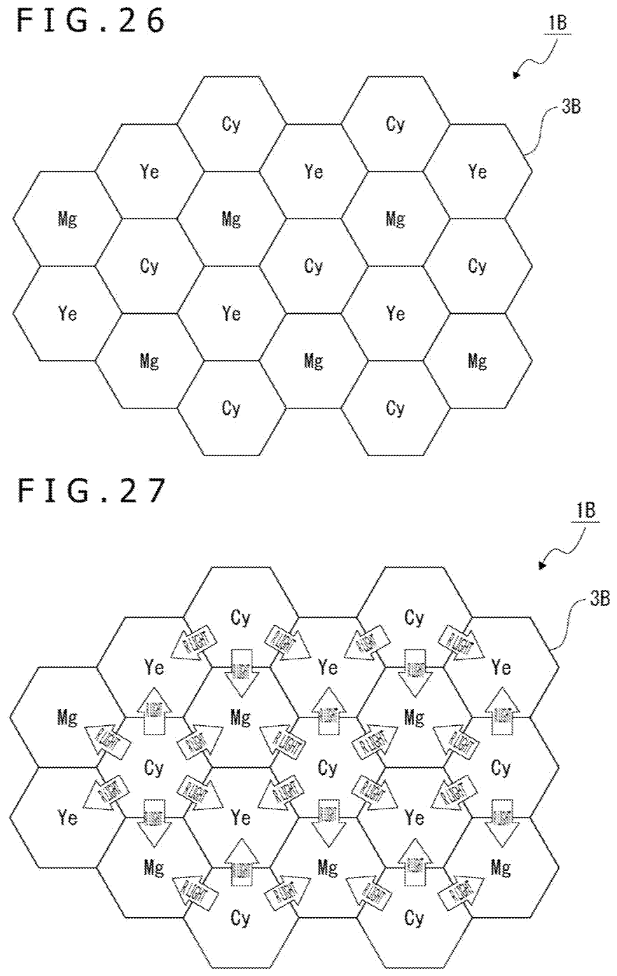

A specific arrangement of the pixels 2 is illustrated in FIG. 26.

FIG. 26 illustrates a part of a pixel array 3B. As illustrated, the cyan pixel Cy is surrounded by six pixels 2, and, as these peripheral pixels 2, the magenta pixels Mg and the yellow pixels Ye are alternately arranged.

The magenta pixel Mg is also similarly surrounded by the cyan pixels Cy and the yellow pixels Ye. The yellow pixel Ye is surrounded by the cyan pixels Cy and the magenta pixels Mg.

The spectroscopic element 8c of the cyan pixel Cy makes the R light which is dispersed from the incident light, incident to the peripheral magenta pixels Mg and yellow pixels Ye as illustrated in FIG. 27.

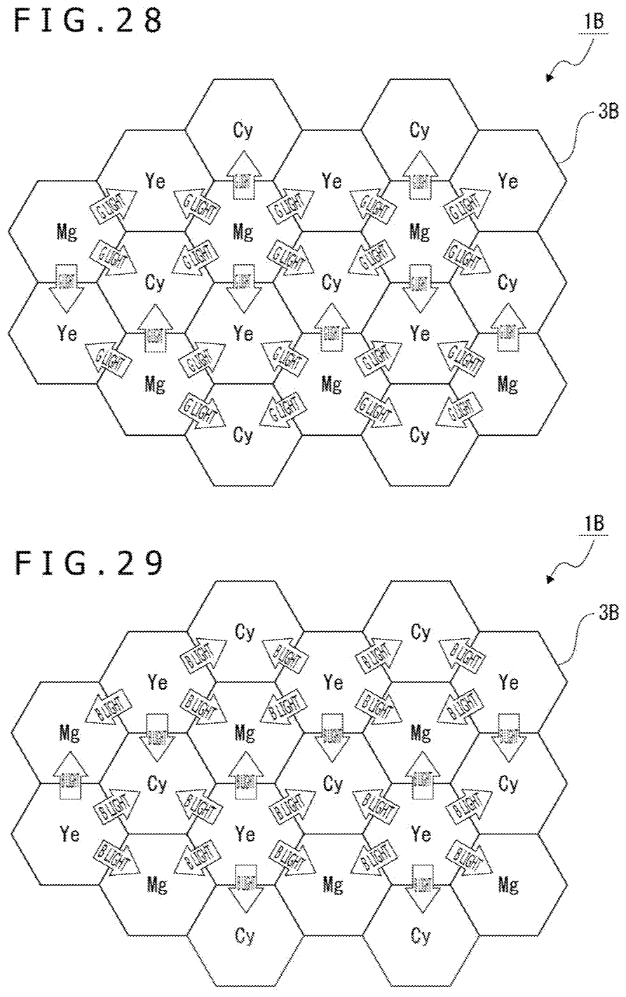

The spectroscopic element 8m of the magenta pixel Mg makes the G light which is dispersed from the incident light, incident to the peripheral cyan pixels Cy and yellow pixels Ye as illustrated in FIG. 28.

The spectroscopic element 8y of the yellow pixel Ye makes the B light which is dispersed from the incident light, incident to the peripheral cyan pixels Cy and magenta pixels Mg as illustrated in FIG. 29.

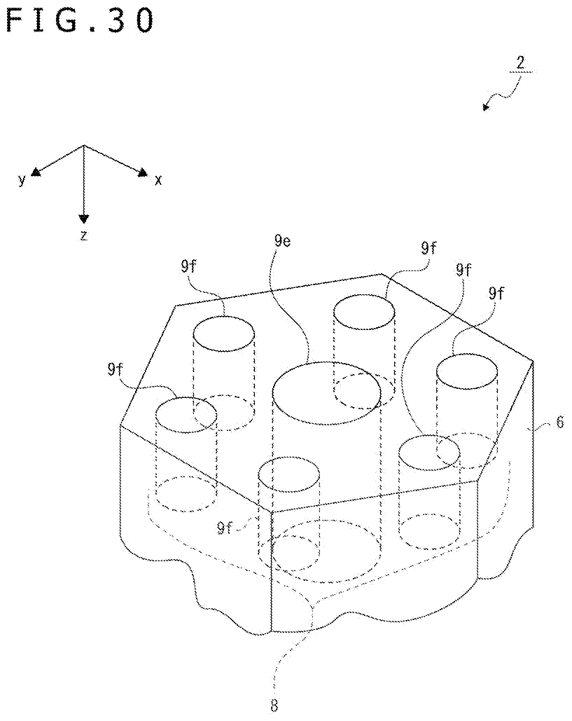

An arrangement example of the microstructures 9 forming the spectroscopic element 8 provided to each pixel 2 is illustrated in FIG. 30.

FIG. 30 illustrates the end surface of the transparent layer 6 on the light incident side. As illustrated, there are provided one fifth microstructure 9e arranged in a substantially center portion and six sixth microstructures 9f on the xy plane of the pixel 2.

The sixth microstructure 9f is arranged at constant intervals so as to surround the fifth microstructure 9e.

The sixth microstructure 9f is configured such that the phase of light in a predetermined wavelength band (for example, the B light) lags with respect to the fifth microstructure 9e, and the light in the predetermined wavelength band is not incident to the photoelectric converter 7 positioned directly below the pixel 2 and is made incident to the photoelectric converter 7 of the peripheral adjacent pixels 2.

As appreciated from each drawing, the spectroscopic element 8 provided to each pixel 2 executes the dispersion such that the light in the predetermined wavelength range is made incident equally toward the peripheral six pixels 2. In other words, it is only required to emit the dispersed light in a concentric circle form.

That is, it is not required to execute the dispersion while limiting the direction such that only a pixel 2 positioned in a specific direction on the xy plane receives the dispersed light, hence the spectroscopic element 8 can easily be designed, and a degree of difficulty of production can be reduced. With this configuration, it is possible to achieve an increase in design accuracy and an increase in characteristics.

Moreover, it is only required for each spectroscopic element 8 to execute the dispersion for one of the R light, the G light, and the B light as a target, hence the production becomes easy, and the filter characteristics can be increased.

### 6. Fourth Embodiment

An imaging element 1c in a fourth embodiment uses the spectroscopic element 8 provided with microstructures 9 to disperse the R light, the G light, and the B light into light in further fine wavelength bands.

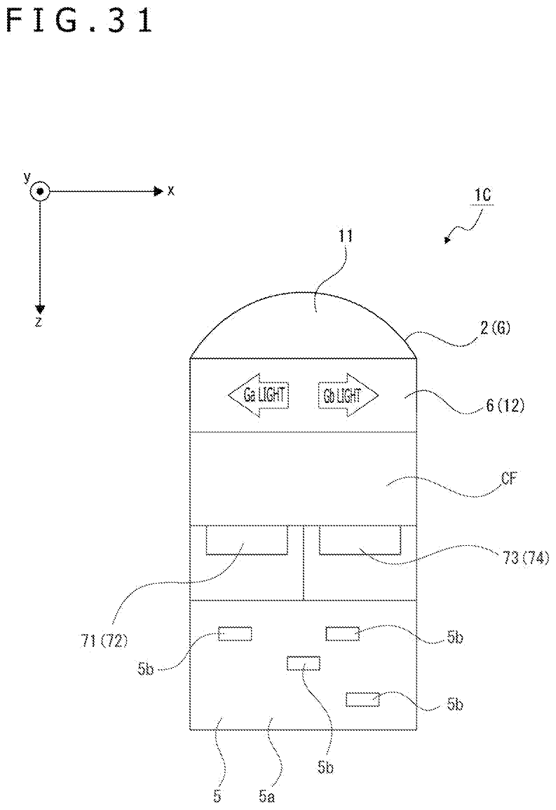

A configuration example in a case in which the pixel 2 is the green pixel G is illustrated in FIG. 31.

The green pixel G in the present embodiment includes an on-chip microlens 11, the transparent layer 6, a color filter CF, and four photoelectric converters 71, 72, 73, and 74.

The incident light is dispersed in the x-axis direction according to whether the wavelength is longer or shorter than a specific wavelength by forming microstructures 9, not illustrated, in the transparent layer 6. That is, the transparent layer 6 functions as a color splitter 12 which disperses the incident light according to the wavelength. Note that the color splitter 12 provided to the green pixel G executes dispersion by use of a center wavelength in a wavelength range considered as the G light as a reference.

In the following description, the G light closer to the B light is referred to as Ga light, and the G light closer to the R light is referred to as Gb light. In other words, a component of the G light on a shorter wavelength side is referred to as Ga light, and a component of the the G light on a longer wavelength side is referred to as Gb light.

Specifically, the B light and the G light closer to the B light (Ga light) are dispersed to a direction in which the photoelectric converters 71 and 72 are present and the G light closer to the R light (Gb light) and the R light are dispersed to a direction on which the photoelectric converters 73 and 74 are present.

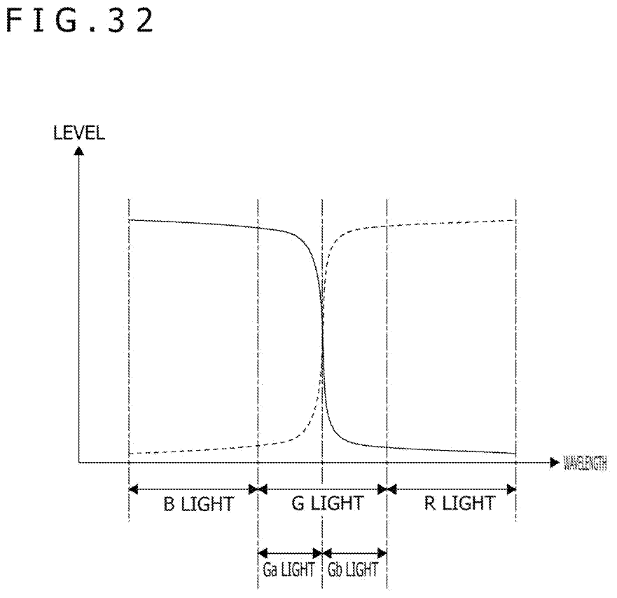

For the transmission spectrum of the color splitter 12, a graph having the wavelength on the horizontal axis and a level of transmission light on the vertical axis is illustrated in FIG. 32.

A graph in a solid line in FIG. 32 is a transmission spectrum of the color splitter 12 for the photoelectric converters 71 and 72. Moreover, a graph in a broken line in FIG. 32 is a transmission spectrum of the color splitter 12 for the photoelectric converters 73 and 74.

As illustrated, the color splitter 12 disperses the B light and the Ga light, and the Gb light and the R light toward directions different from each other on the x axis.

The color filter CF of the green pixel G transmits only the G light. Thus, the B light and the R light of the light dispersed by the color splitter 12 are cut by the color filter CF, and, consequently, the Ga light is incident to the photoelectric converters 71 and 72, and the Gb light is incident to the photoelectric converters 73 and 74.

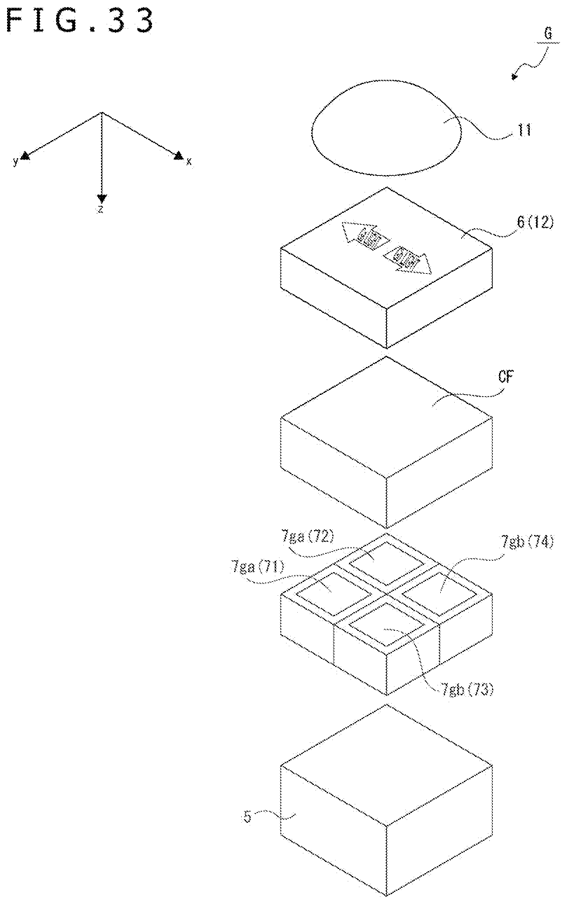

An exploded perspective view of the green pixel G is illustrated in FIG. 33.

As illustrated, the photoelectric converters 71 and 72 are configured as photoelectric converters 7ga which receive the Ga light and the photoelectric converters 73 and 74 are configured as photoelectric converters 7gb which receive the Gb light.

As a result, a component of the Ga light can be detected on the basis of a pixel signal acquired in the photoelectric converters 71 and 72, and a component of the Gb light can be detected on the basis of a pixel signal acquired in the photoelectric converters 73 and 74.

Thus, color reproducibility for the G light can be increased. Specifically, detection as the G light is enabled by treating the pixel signal of the Ga light and the pixel signal of the Gb light as a sum thereof. Further, a color of an image can be calculated on the basis of the light dispersed into the larger number of colors by treating the pixel signal of the Ga light and the pixel signal of the Gb light independently, and hence the color reproducibility can be increased.

Moreover, the Ga light received in the photoelectric converter 71 and the Ga light received in the photoelectric converter 72 are based on the incident light which has passed through respective pupils divided in the y-axis direction. Thus, a phase difference in the y-axis direction can be detected by comparing the pixel signal acquired from the photoelectric converter 71 and the pixel signal acquired from the photoelectric converter 72 with each other. As a result, a defocus amount can be calculated.

This similarly applies to the photoelectric converter 73 and the photoelectric converter 74, and a phase difference between beams of the Gb light which have passed through respective pupils divided in the y-axis direction can be detected.

That is, the color splitter 12 has the x-axis direction as the disperse direction for the incident light and has the y-axis direction as the detection direction for the phase difference.

A description is now given of a configuration which can increase the color reproducibility and can detect the phase difference in a case in which the red pixel R which receives the R light, the green pixel G which receives the G light, and the blue pixel B which receives the B light take a form of the Bayer array.

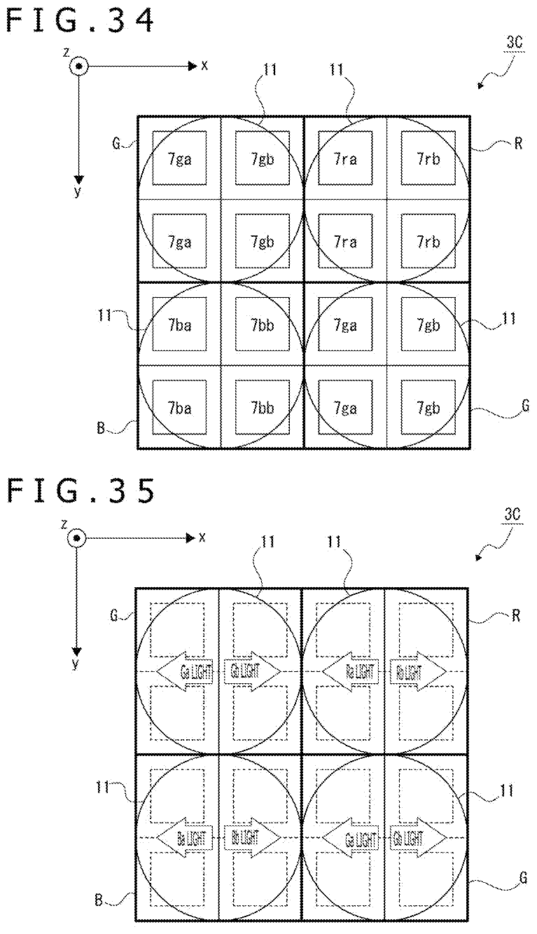

As illustrated in FIG. 33 and FIG. 34, each pixel 2 (the red pixel R, the green pixel G, or the blue pixel B) provided to a pixel array 3C of the imaging element 1C is provided with one on-chip microlens 11 and the four photoelectric converters 7. As the photoelectric converters 7 of the green pixel G, there are provided the photoelectric converters 7ga which receive the Ga light being the G light closer to the B light and the photoelectric converters 7gb which receive the Gb light being the G light closer to the R light.

As the photoelectric converters 7 of the blue pixel B, there are provided photoelectric converters 7ba which receive Ba light which is shorter in wavelength than light having a center wavelength of the B light (a component of the B light on a shorter wavelength side) and photoelectric converters 7bb which receive Bb light which is the B light closer to the G light (a component of the B light on a longer wavelength side).

As the photoelectric converter 7 of the red pixel R, there are provided photoelectric converters 7ra which receive Ra light which is the R light close to the G light (a component of the R light on a shorter wavelength side) and a photoelectric converters 7rb which receive Rb light which is longer in wavelength than light having a center wavelength of the R light (a component of the R light on a longer wavelength side).

As a result, as illustrated in FIG. 34 and FIG. 35, each pixel 2 can disperse the incident light in the x-axis direction and can detect the phase difference in the y-axis direction.

A description is now given of some examples of a configuration which enables not only the detection of the phase difference in the y-axis direction, but also detection of a phase difference in the x-axis direction.

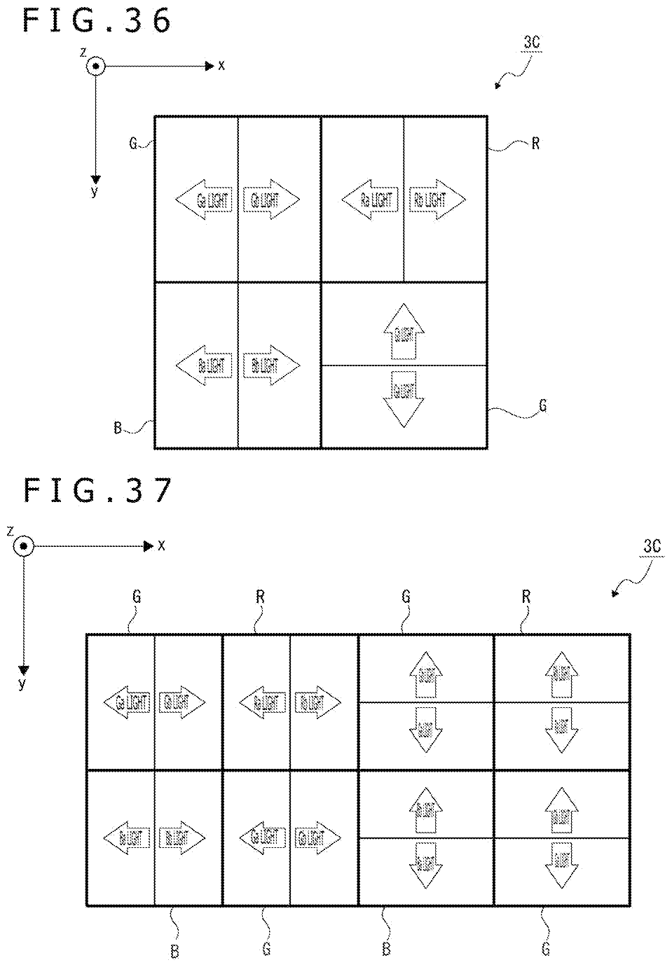

FIG. 36 illustrates an example in which the G pixels which are more in number than the R pixel and the B pixel in the Bayer array have the function of detecting the phase difference in the x-axis direction.

That is, the color splitter 12 of each of substantially a half of the G pixels is configured such that the dispersion direction of the incident light is the x-axis direction, and the color splitter 12 of each of substantially a remaining half of the G pixels is configured such that the dispersion direction of the incident light is the y-axis direction.

Thus, the phase difference in the x-axis direction can be detected on the basis of the pixel signal output from the G pixel.

Another example of the configuration which enables not only the detection of the phase difference in the y-axis direction, but also the detection of the phase difference in the x-axis direction is illustrated in FIG. 37.

In this configuration, each pixel block 10B including the two pixels in each of the vertical and horizontal directions forming the Bayer array has a different dispersion direction. Specifically, as illustrated in FIG. 37, while the dispersion direction of the incident light is the x-axis direction in a pixel block 10BX, the dispersion direction of the incident light is the y-axis direction in an adjacent pixel block 10BY.

As a result, the configuration illustrated in FIG. 37 is enabled to detect the phase difference in each of the x-axis direction and the y-axis direction and to increase the color reproducibility.

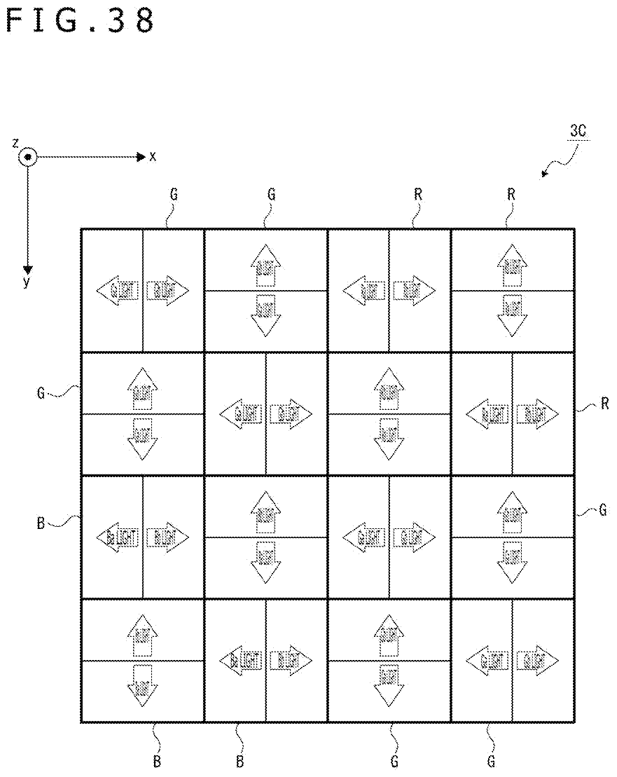

A still another example is illustrated in FIG. 38.

In the pixel array 3C illustrated in FIG. 38, a green pixel block 13G being a set of four green pixels G, a red pixel block 13R being a set of four red pixels R, and a blue pixel block 13B being a set of four blue pixels B are arranged as units of a Bayer array.

Each pixel block 13 includes four pixels 2 and is provided with four on-chip microlenses 11 and 16 photoelectric converters 7.

In each of the pixel blocks 13G, 13R, and 13B, the dispersion direction is different between the pixels adjacent to each other in the x-axis direction and between the pixels adjacent to each other in the y-axis direction.

By employing such a configuration described above, the detection of the phase difference in each of the x-axis direction and the y-axis direction and the increase in color reproducibility are also enabled.

### 7. Fifth Embodiment

An imaging element 1D in a fifth embodiment is a combination of the first embodiment or the second embodiment and the fourth embodiment. That is, in the pixel 2 in the fifth embodiment, light in an unnecessary wavelength band is dispersed to the adjacent pixels 2 by providing the spectroscopic element 8 including the microstructures 9 and an increase in the color reproducibility is achieved by providing the color splitter 12 which splits incident light in a specific wavelength band.

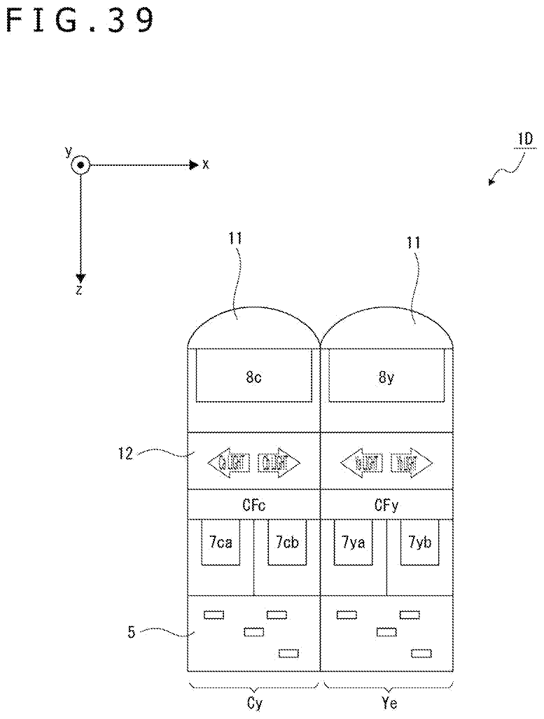

A specific description is given of the cyan pixel Cy and the yellow pixel Ye as an example with reference to FIG. 39.

The cyan pixel Cy is provided with the one on-chip microlens 11, one of the spectroscopic element 8c, one color splitter 12c, one color filter CFc, four of the photoelectric converters 7c, and the wiring layer 5.

Of the four photoelectric converters 7c, two are configured as photoelectric converters 7ca for receiving cyan light having a shorter wavelength, and the remaining two are configured as photoelectric converters 7cb for receiving cyan light having a longer wavelength.

The color filter CFc is configured as a filter which does not pass the R light.

The yellow pixel Ye similarly is provided with the one on-chip microlens 11, one of the spectroscopic element 8y, one color splitter 12y, one color filter CFy, two photoelectric converters 7ya, two photoelectric converters 7yb, and the wiring layer 5.

The color filter CFy is configured as a filter which does not pass the B light.

The magenta pixel Mg, not illustrated, is provided with the spectroscopic element 8m, a color splitter 12m, a color filter CFm, two photoelectric converters 7ma, and two photoelectric converters 7mb. Similarly, the green pixel G is provided with the spectroscopic element 8g, a color splitter 12g, a color filter CFg, two of the photoelectric converters 7ga, and two of the photoelectric converters 7gb.

By using the pixels 2 in the present embodiment, both of the increase in the characteristics through the dispersion and the increase in color reproducibility can be achieved.

Note that, in FIG. 39, each pixel 2 includes the color filter CF, but the pixel 2 may not include the color filter CF.

That is, the light in the unnecessary wavelength band for each pixel 2 is dispersed to other pixels by the color splitter 12, and hence, similar effect can be obtained without the color filter CF.

### Modification Examples

In each example described above, there is described the example in which the spectroscopic element 8 is constructed by forming the microstructures 9 such that the end surfaces thereof are exposed on the surface of the transparent layer 6.

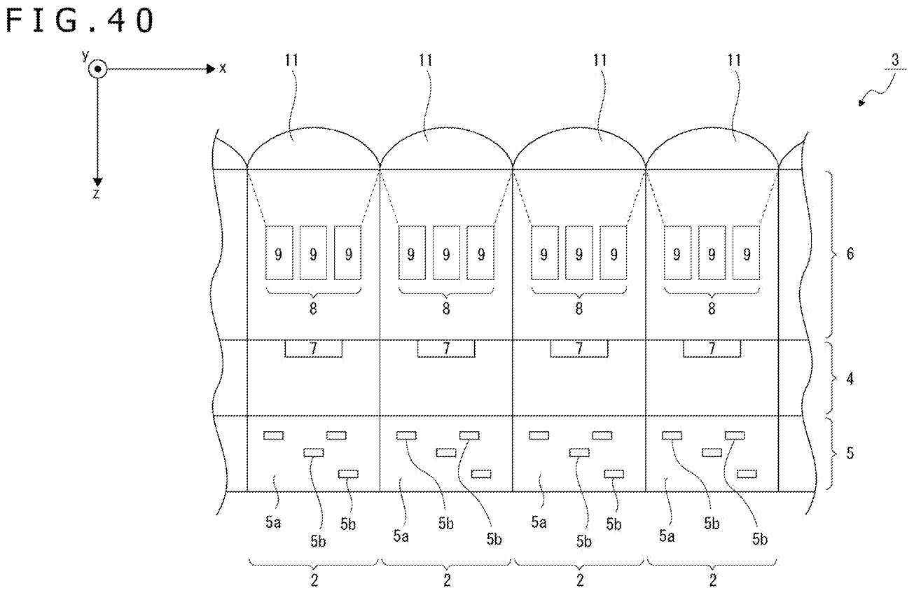

The configuration is not limited to this example, and the microstructures 9 may be formed such that the end surfaces thereof are not exposed on the surface of the transparent layer 6. Specifically, as illustrated in FIG. 40, the spectroscopic element 8 may be constructed by forming the microstructures 9 such that the microstructures 9 are fully embedded inside the transparent layer 6.

Moreover, in the first embodiment, the second embodiment, and the third embodiment, the on-chip microlens 11 may be provided on the light incidence side of the transparent layer 6 (see FIG. 40).

Moreover, in a case in which each pixel 2 is provided with the on-chip microlens 11, the microstructure 9 may be formed in a vicinity of the center of the pixel 2 on the xy plane in consideration of the light-collecting effect of the on-chip microlens 11.

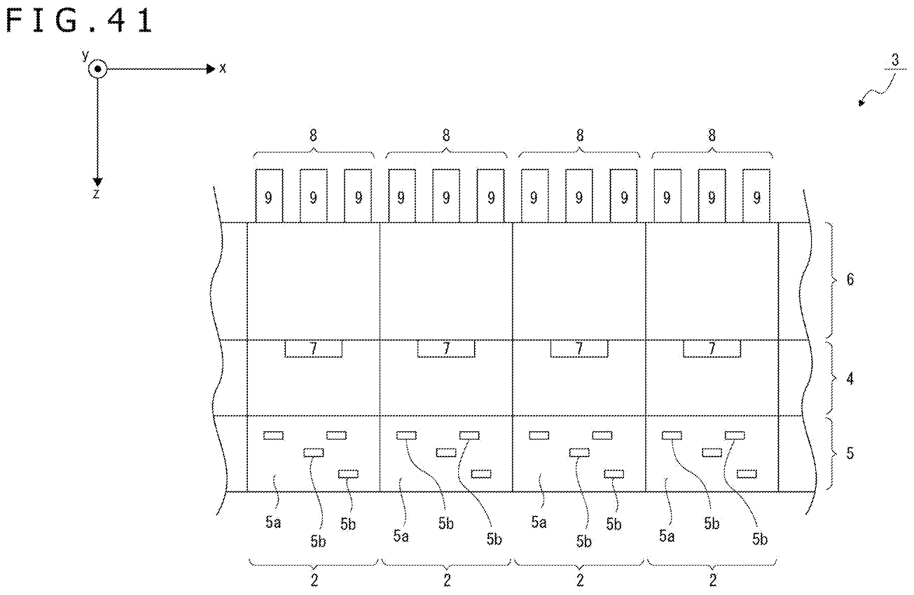

Moreover, as illustrated in FIG. 41, the microstructures 9 may be formed outside the transparent layer 6. In this case, the spectroscopic element 8 may have a light-collecting function for the photoelectric converter 7.

In the third embodiment, there is described such a configuration that the six pixels 2 are arranged around the pixel 2 by configuring the shape of the pixel 2 as the hexagon.

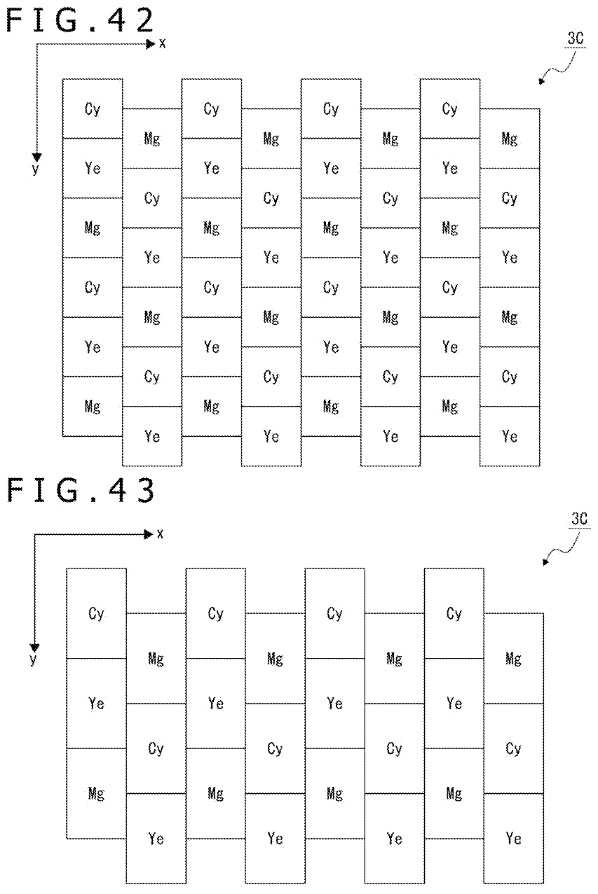

Modification examples thereof are illustrated in FIG. 42 and FIG. 43.

FIG. 42 and FIG. 43 illustrate states in which three magenta pixels Mg and three yellow pixels Ye are arranged around the cyan pixel Cy.

In the example illustrated in FIG. 42, the shape of each pixel 2 is square as viewed from the light incidence side.

Moreover, in the example illustrated in FIG. 43, the shape of each pixel 2 is rectangular as viewed from the light incidence side.

Even with these shapes, actions and effects similar to those of the third embodiment can be obtained. Note that, by configuring the shape of the pixel 2 as a rectangular shape, centers of gravity of the pixels 2 can be arranged so as to form a hexagonal close-packed structure, that is, a regular hexagon when the center of gravities of the pixels 2 are connected to each other.

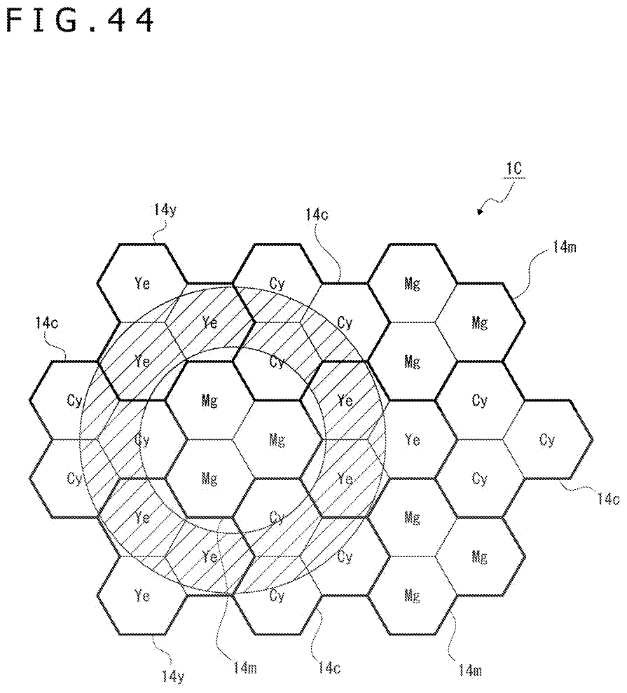

Moreover, as in the third embodiment, another example in which the shape of the pixel 2 is the hexagon is illustrated in FIG. 44. This example is a drawing for illustrating an example of a pixel array in which three pixels which receive light in the same wavelength band are included as one pixel block 14.

Specifically, there are arranged cyan pixel blocks 14c each including three cyan pixels Cy, magenta pixel blocks 14m each including three magenta pixels Mg, and yellow pixel blocks 14y each including three yellow pixels Ye.

In FIG. 44, there is illustrated an emission range of the G light dispersed from the magenta pixels Mg. As illustrated as a hatched region of FIG. 44, there is provided such a configuration that the dispersed G light is incident to the adjacent cyan pixel blocks 14c and yellow pixel blocks 14y and the dispersed G light is not incident to the magenta pixels Mg positioned outside these pixel blocks.

Even in this form, actions and effects similar to those of the third embodiment can be obtained.

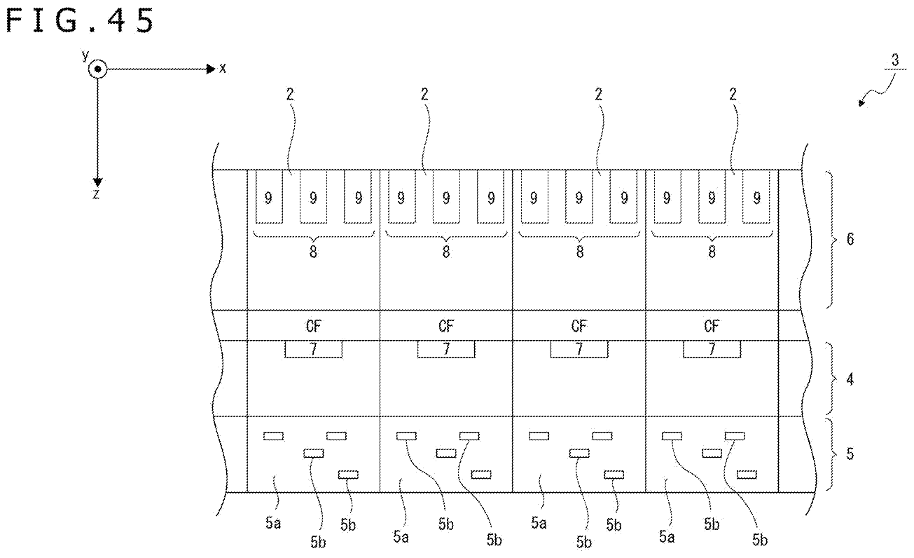

In the imaging elements 1, 1A, and 1B described in the first embodiment, the second embodiment, and the third embodiment, respectively, the example in which the pixel 2 is not provided with the color filter CF is described, but each pixel 2 may include the color filter CF (see FIG. 45).

Specifically, the cyan pixel Cy may be provided with, on the light incident side of the photoelectric converter 7c, the color filter CFc which transmits only the cyan light, the magenta pixel Mg may be provided with, on the light incident side of the photoelectric converter 7m, the color filter CFm which transmits only the magenta light, and the yellow pixel Ye may be provided with, on the light incident side of the photoelectric converter 7y, the color filter CFy which transmits only the yellow light.

Moreover, in a case in which the green pixel G is provided, the green pixel G may be provided with, on the light incident side of the photoelectric converter 7g, the color filter CFg which transmits only the G light.

As a result, each photoelectric converter 7 can avoid reception of light in unnecessary colors, and hence an increase in color reproducibility can be achieved.

Moreover, there is described such an example, for the green pixel G, the photoelectric converter 7g of the green pixel G receives only the G light by the spectroscopic element 8g deflecting the propagation direction of both of the R light and the B light, but the spectroscopic element 8g may be configured to deflect the propagation direction of only one of the R light and the B light. In this case, the photoelectric converter 7g may be configured to receive only the G light by arranging a filter which does not transmit the R light or a filter which does not transmit the B light at a prior stage of the photoelectric converter 7g of the green pixel G. As a result, the configuration of the spectroscopic element 8g can be simplified, and hence an increase in characteristic of the filter function and a cost reduction of the spectroscopic element 8g can be achieved.

### 9. Summary

As described in each example, the imaging element 1 (1A, 1B, 1D) includes the pixel array 3 (3B, 3C) that includes the pixels 2 that are arranged two-dimensionally and each of which has the photoelectric converter 7 (7c, 7m, 7y, 7g, 71, 72, 73, 74) and the spectroscopic element 8 (8c, 8m, 8y, 8g) that is arranged on the light incident side of the photoelectric converter 7 and disperses the light in the predetermined wavelength range, in which the pixels 2 include the cyan pixels Cy that receive the cyan light, the magenta pixels Mg that receive the magenta light, and the yellow pixels Ye that receive the yellow light.

As a result, the light which is not received in the photoelectric converter 7c of the cyan pixel Cy is only the R light of the red light (R light), the green light (G light), and the blue light (B light). Moreover, the light which is not received in the photoelectric converter 7m of the magenta pixel Mg is only the G light, and the light which is not received in the photoelectric converter 7y of the yellow pixel Ye is only the B light.

Moreover, the photoelectric converters 7 which receive the R light are the two types of photoelectric converters (photoelectric converters 7m and 7y) of the photoelectric converters 7c, 7m, and 7y. Each of the G light and the B light can similarly be received by the two types of photoelectric converters.

Thus, it is not required to excessively narrow the propagation direction of the light dispersed by the spectroscopic element 8. In other words, the propagation direction of the dispersed light can be widened. Thus, a decrease in difficulty of production of the spectroscopic element 8 and an increase in characteristics of the spectroscopic element 8 such as the reduction in color mixture can be achieved.

Moreover, the incident light can effectively be used without cutting a specific wavelength component in the incident light, and hence, efficiency of use of the incident light can be increased.

As described with reference to each of FIG. 4 to FIG. 13, in the imaging element 1 (1A, 1B, 1D), the spectroscopic element 8 of the cyan pixel Cy may be a first spectroscopic element (spectroscopic element 8c) that disperses the red light (R light) toward the magenta pixel Mg and the yellow pixel Ye therearound, the spectroscopic element 8 of the magenta pixel Mg may be a second spectroscopic element (spectroscopic element 8m) that disperses the green light (G light) toward the cyan pixel Cy and the yellow pixel Ye therearound, and the spectroscopic element 8 of the yellow pixel Ye may be a third spectroscopic element (spectroscopic element 8y) that disperses the blue light (B light) toward the cyan pixel Cy and the magenta pixel Mg therearound.

As a result, it is not required to excessively limit the disperse direction in the spectroscopic element 8 (8c, 8m, 8y).

Thus, the degree of difficulty of the production of the spectroscopic element 8 can be reduced, and the characteristics of the spectroscopic element 8 can be increased.

As described with reference to FIG. 45 and the like, in the imaging element 1 (1A, 1B, 1C, 1D), the cyan pixel Cy may include the cyan color filter (color filter CFc) that transmits the cyan light, the magenta pixel Mg may include the magenta color filter (color filer CFm) that transmits the magenta light, and the yellow pixel Ye may include the yellow color filter (color filer CFy) that transmits the yellow light.

As a result, the R light leaking to the cyan pixel Cy can be cut by the cyan color filer (color filter CFc). Similarly, the G light leaking to the magenta pixel Mg can be cut by the color filter CFm and the B light leaking to the yellow pixel Ye can be cut by the color filter CFy.

Thus, an increase in characteristics of the imaging element can be achieved. Moreover, a target accuracy of the spectroscopic element 8 can be reduced, and hence the degree of difficulty of the production of the spectroscopic element 8 can be reduced.

As described in the second embodiment and the like, in the imaging element 1A, the pixel 2 may include the green pixel G that receives the green light (G light), and the pixel array 3 may include the pixel blocks 10 (10A) each of which includes two pixels each in the vertical direction and the horizontal direction including the cyan pixel Cy, the magenta pixel Mg, the yellow pixel Ye, and the green pixel G, and the pixel blocks 10 (10A) are continuously arranged vertically and horizontally.

As a result, the pixel 2 adjacent in either one of the x-axis direction and the y-axis direction can be included in the propagation range of the dispersed light in the spectroscopic element 8.

Thus, it is not required to limit the disperse direction of the spectroscopic element 8 such that the dispersed light is received by only the pixels 2 positioned in the diagonal directions, and hence it is possible to prevent the dispersed light from leaking to the pixels 2 which are intended not to receive the dispersed light.

As described with reference to each of FIG. 14 to FIG. 17, in the imaging element 1 (1A, 1C, 1D), the spectroscopic element 8 of the green pixel G may be a fourth spectroscopic element (spectroscopic element 8g) that disperses the red light (R light) toward the magenta pixel Mg and the yellow pixel Ye therearound and disperses the blue light (B light) toward the cyan pixel Cy and the magenta pixel Mg therearound.

That is, the plurality of types of the pixel 2 which can receive the R light and the plurality of types of the pixel 2 which can receive the B light are present. Thus, also for the green pixel G, it is not required to excessively limit the dispersion direction of the spectroscopic element 8g.

As a result, the degree of difficulty of production of the spectroscopic element 8g can be reduced, and the characteristics of the spectroscopic element 8g can be increased.

As described with reference to each of FIG. 7 to FIG. 10, in the imaging element 1 (1A, 1C, 1D), the second spectroscopic element (spectroscopic element 8m) may disperse the green light (G light) toward the cyan pixel Cy, the yellow pixel Ye, and the green pixel G therearound.

That is, the dispersion direction of the spectroscopic element 8m of the magenta pixel Mg may include the green pixel G.

Thus, also in the configuration in which the color reproducibility is increased by including the green pixel G, the disperse direction (disperse range) of the spectroscopic element 8m of the magenta pixel Mg can be wide, and hence the degree of difficulty of the production of the spectroscopic element 8m can be reduced.

As described in the second embodiment and the like, in the imaging element 1A (1C, 1D), the first spectroscopic element (spectroscopic element 8c), the second spectroscopic element (spectroscopic element 8m), the third spectroscopic element (spectroscopic element 8y), and the fourth spectroscopic element (spectroscopic element 8g) may execute the dispersion toward the photoelectric converter 7 (7c, 7m, 7y, 7g) in the same pixel block 10 (10A, 10B, 10X, 10Y).

As a result, the spectroscopic element 8 is only required to execute the dispersion toward other two pixels 2 in the pixel block 10.

In particular, there may be provided such a configuration that the light dispersed in the spectroscopic elements 8c, 8m, and 8y of the cyan pixel Cy, the magenta pixel Mg, and the yellow pixel Ye is made incident to one pixel 2 adjacent in the x-axis direction or the y-axis direction, and a structure of the spectroscopic element 8 can be simplified.

As described in the second embodiment and the like, in the imaging element 1A, the first spectroscopic element (spectroscopic element 8c) may disperse the red light (R light) such that the red light is received by only either one of the magenta pixel Mg and the yellow pixel Ye within the same pixel block 10 (10A, 10B, 10X, 10Y), the second spectroscopic element (spectroscopic element 8m) may disperse the green light (G light) such that the green light (G light) is received by only any one of the cyan pixel Cy, the yellow pixel Ye, and the green pixel G within the same pixel block 10, the third spectroscopic element (spectroscopic element 8y) may disperse the blue light (B light) such that the blue light is received by only either one of the cyan pixel Cy and the magenta pixel Mg within the same pixel block 10, and the fourth spectroscopic element (spectroscopic element 8g) may disperse the red light (R light) such that the red light is received by only either one of the magenta pixel Mg and the yellow pixel Ye within the same pixel block 10 and may disperse the blue light (B light) such that the blue light (B light) is received by only either one of the cyan pixel Cy and the magenta pixel Mg within the same pixel block 10.

As a result, the propagation direction of the light dispersed in the spectroscopic elements 8c, 8m, and 8y of the cyan pixel Cy, the magenta pixel Mg, and the yellow pixel Ye can be limited to the one direction and can be aligned with the arrangement direction of the pixels 2 (x-axis direction or the y-axis direction), and hence the structure of the spectroscopic element 8 can be simplified.

Moreover, also in the spectroscopic element 8g of the green pixel G, each of the dispersion direction of the R light and the dispersion direction of the B light can be limited to the one direction and can be aligned with the arrangement direction (x-axis direction or y-axis direction) of the pixels 2.

As described with reference to FIG. 45 and the like, in the imaging element 1 (1A, 1C, 1D), the green pixel G may include the green color filter (color filter CFg) which transmits the green light (G light).

As a result, the R light and the B light leaking to the green pixel G can be cut by the green color filter (color filter CFg).

Thus, an increase in characteristics of the imaging element can be achieved. Moreover, the target accuracy of the spectroscopic element 8g can be reduced, and hence the degree of difficulty of the production of the spectroscopic element 8 can be reduced.

As described with reference to FIG. 1, FIG. 2, and the like, in the imaging element 1 (1A, 1C, 1D), the pixel 2 may have the rectangular shape as viewed from the light incident side, and the pixel array 3 (3C) may include the pixels arranged in the first direction (for example, the x-axis direction) and the second direction (for example, the y-axis direction) orthogonal to the first direction at the equal intervals.

As a result, the effects described above can be obtained in the configuration which employes the general pixel arrangement.

As described in the third embodiment and the modification examples, in the imaging element 1B, the pixel 2 arranged in the portion other than the outer most peripheral portion of the pixel array 3B may be arranged so as to be surrounded by six of the pixels 2.

As a result, the effects described above can be obtained in the configuration which employes the honeycomb structure or the configuration in which the pixels 2 each in the rectangular shape are arranged similarly to the honeycomb structure.

As described in the third embodiment and the modification examples, in the imaging element 1B, the six adjacent pixels 2 of the cyan pixel Cy may be either one of the yellow pixels Ye and the magenta pixels Mg, the six adjacent pixels 2 of the yellow pixel Ye may be either one of the cyan pixels Cy and the magenta pixels Mg, and the six adjacent pixels 2 of the magenta pixel Mg may be either one of the cyan pixels Cy and the yellow pixels Ye.

As a result, the R light which is intended not to be received in the cyan pixel Cy may be received by any peripheral pixel. That is, it is only required that the spectroscopic element 8c of the cyan pixel Cy is configured such that the R light dispersed from the incident light propagates toward the peripheral pixels 2 in the concentric circle form. That is, it is not required to limit the propagation direction on the xy plane, and it is only required that the R light is incident to the photoelectric converters 7 of the adjacent pixels 2 positioned in the predetermined range of the distance from the photoelectric converter 7c positioned immediately below the spectroscopic element 8c. This similarly applies to the magenta pixel Mg and the yellow pixel Ye.

Thus, the design accuracy of the spectroscopic element 8 can be increased, and hence the characteristics of the spectroscopic element 8 can be increased.

As described in the third embodiment, in the imaging element 1B, the pixel 2 may have the hexagonal shape as viewed from the light incident side.

The effects described above can be obtained in the configuration which employes the honeycomb structure. Moreover, the efficiency of use of the incident light can be increased by employing the honeycomb structure, and hence a resolution in a gradation direction can be increased.

As described with reference to FIG. 3, FIG. 18, and the like, in the imaging element 1 (1A, 1B, 1C, 1D), the spectroscopic element 8 (8c, 8m, 8y, 8g) may include the plurality of types of microstructure 9 (9a, 9b, 9c, 9d, 9e, 9f) having the refractive indices different from one another.

As a result, it is possible to use the microstructures 9 to disperse light in a specific wavelength band in the incident light toward another pixel 2.

As described with reference to FIG. 40 and the like, in the imaging element 1 (1A, 1B, 1D), the on-chip microlens 11 may be provided on the light incident side of the spectroscopic element 8 (8c, 8m, 8y, 8g).

As a result, the incident light can efficiently be collected on the spectroscopic element 8, and hence the resolution in the gradation direction can be increased. Moreover, it is not required that the spectroscopic element 8 has an excessive light collection function, and hence the design accuracy of the spectroscopic element 8 can be increased.

As described in the fourth embodiment and the fifth embodiment, the imaging element 1C and the imaging element 1D each include the pixel array 3 that includes the pixels 2 that are arranged two-dimensionally and each of which has the photoelectric converter that includes a first-type photoelectric converter (for example, the photoelectric converter 7ga in the green pixel

G) and a second-type photoelectric converter (for example, the photoelectric converter 7gb in the green pixel G), the prior stage spectroscopic element (spectroscopic element 8, 8c, 8m, 8y, 8g) that disperses the light in the predetermined wavelength range of the incident light toward another pixel, and the posterior stage spectroscopic element (color splitter 12, 12g, 12c, 12y, 12m) that is arranged between the prior stage spectroscopic element (spectroscopic element 8) and the photoelectric converter, that disperses the light that has passed through the prior stage spectroscopic element (spectroscopic element 8) to the light in the first wavelength band (the light having the wavelength shorter than the center wavelength of the G light) and the light in the second wavelength band (the light having the wavelength longer than the center wavelength of the G light) on the basis of the reference wavelength (the center wavelength of the G light in the green pixel G), that causes the first type photoelectric converter (for example, the photoelectric converter 7ga) to receive the light in the first wavelength band, and that causes the second type photoelectric converter (for example, the photoelectric converter 7gb) to receive the light in the second wavelength band.

As a result of the provision of the posterior stage spectroscopic element (color splitter 12), it is possible to narrow the wavelength range of the light received in each of the photoelectric converter (for example, each of the photoelectric converters 7ga and 7gb in the green pixel G).

Thus, the color reproducibility can be increased.

As described in the fourth embodiment and the fifth embodiment, the imaging element 1C and the imaging element 1D may include the plurality of the first type photoelectric converters (for example, the photoelectric converters 7ga in the green pixel G) and the plurality of the second type photoelectric converters (for example, the photoelectric converters 7gb in the green pixel G).

As a result, it is possible to enable the imaging elements 1C and 1D to have the pupil division function which divides the pupil in the arrangement direction of the first type photoelectric converters. Thus, the defocus amount can be calculated and hence can be used for focusing control.

Note that the effects described in the present specification are merely illustrative and not restrictive, and other effects may also be achieved.

Moreover, the examples described above may be combined in any way, and the various actions and effects can be obtained even in a case in which the various combinations are used.

### 10. Present Technology

In addition, the present technology can also adopt the following configurations.

(1)

An imaging element including:
a pixel array that includes pixels that are arranged two-dimensionally and each of which has a photoelectric converter and a spectroscopic element that is arranged on a light incident side of the photoelectric converter and disperses light in a predetermined wavelength range,
in which the pixels include cyan pixels that receive cyan light, magenta pixels that receive magenta light, and yellow pixels that receive yellow light.
   (2)

The imaging element according to (1) above,
in which the spectroscopic element of the cyan pixel is a first spectroscopic element that disperses red light toward the magenta pixel and the yellow pixel therearound,
the spectroscopic element of the magenta pixel is a second spectroscopic element that disperses green light toward the cyan pixel and the yellow pixel therearound, and
the spectroscopic element of the yellow pixel is a third spectroscopic element that disperses blue light toward the cyan pixel and the magenta pixel therearound.
   (3)

The imaging element according to (1) or (2) above,
in which the cyan pixel includes a cyan color filter that transmits cyan light,
the magenta pixel includes a magenta color filter that transmits magenta light, and
the yellow pixel includes a yellow color filter that transmits yellow light.
   (4)

The imaging element according to (2) above,
in which the pixel includes a green pixel that receives the green light, and
the pixel array includes pixel blocks each of which includes two pixels each in a vertical direction and a horizontal direction including the cyan pixel, the magenta pixel, the yellow pixel, and the green pixel and that are continuously arranged vertically and horizontally.
   (5)

The imaging element according to (4) above,
in which the spectroscopic element of the green pixel is a fourth spectroscopic element that disperses the red light toward the magenta pixel and the yellow pixel therearound and disperses the blue light toward the cyan pixel and the magenta pixel therearound.
   (6)

The imaging element according to (5) above,
in which the second spectroscopic element disperses the green light toward the cyan pixel, the yellow pixel, and the green pixel therearound.
   (7)

The imaging element according to (5) or (6) above,
in which the first spectroscopic element, the second spectroscopic element, the third spectroscopic element, and the fourth spectroscopic element execute the dispersion toward the photoelectric converter in the same pixel block.
   (8)

The imaging element according to (7) above,
in which the first spectroscopic element disperses the red light such that the red light is received by only either one of the magenta pixel and the yellow pixel within the same pixel block,
the second spectroscopic element disperses the green light such that the green light is received by only any one of the cyan pixel, the yellow pixel, and the green pixel within the same pixel block,
the third spectroscopic element disperses the blue light such that the blue light is received by only either one of the cyan pixel and the magenta pixel within the same pixel block, and
the fourth spectroscopic element disperses the red light such that the red light is received by only either one of the magenta pixel and the yellow pixel within the same pixel block and disperses the blue light such that the blue light is received by only either one of the cyan pixel and the magenta pixel within the same pixel block.
   (9)

The imaging element according to any one of (4) to (8) above,
in which the green pixel includes a green color filter which transmits the green light.
   (10)

The imaging element according to any one of (1) to (9) above,
in which the pixel has a rectangular shape as viewed from a light incident side, and
the pixel array includes the pixels arranged in a first direction and a second direction orthogonal to the first direction at equal intervals.
   (11)

The imaging element according to any one of (1) to (3) above,
in which the pixel arranged in a portion other than an outer most peripheral portion of the pixel array is arranged so as to be surrounded by six of the pixels.
   (12)

The imaging element according to (11) above,
in which the six adjacent pixels of the cyan pixel are either one of the yellow pixels and the magenta pixels,
the six adjacent pixels of the yellow pixel are either one of the cyan pixels and the magenta pixels, and
the six adjacent pixels of the magenta pixel are either one of the cyan pixels and the yellow pixels.
   (13)

The imaging element according to (11) or (12) above,
in which the pixel has a hexagonal shape as viewed from a light incident side.
   (14)

The imaging element according to any one of (1) to (13) above,
in which the spectroscopic element includes a plurality of types of microstructures having refractive indices different from one another.
   (15)

The imaging element according to any one of (1) to (14) above, including:
an on-chip microlens on a light incident side of the spectroscopic element.
   (16)

An imaging element including:
a pixel array that includes pixels arranged two-dimensionally and each of which has a photoelectric converter that includes a first-type photoelectric converter and a second-type photoelectric converter, a prior stage spectroscopic element that disperses light in a predetermined wavelength range of incident light toward another pixel, and a posterior stage spectroscopic element that is arranged between the prior stage spectroscopic element and the photoelectric converter, that disperses the light that has passed through the prior stage spectroscopic element to light in a first wavelength band and light in a second wavelength band, on the basis of a reference wavelength, that causes the first type photoelectric converter to receive the light in the first wavelength band, and that causes the second type photoelectric converter to receive the light in the second wavelength band.
   (17)

The imaging element according to (16) above, including:
a plurality of the first type photoelectric converters and a plurality of the second type photoelectric converters.

### REFERENCE SIGNS LIST

1, 1A, 1B, 1C, 1D: Imaging element
2: Pixel
3, 3B, 3C: Pixel array
7, 7c, 7m, 7y, 7g: Photoelectric converter
71, 72, 73, 74: Photoelectric converter
7ga, 7gb, 7ra, 7rb, 7ba, 7bb: Photoelectric converter
8: Spectroscopic element
8c: Spectroscopic element (first spectroscopic element)
8m: Spectroscopic element (second spectroscopic element)
8y: Spectroscopic element (third spectroscopic element)
8g: Spectroscopic element (fourth spectroscopic element)
8, 8c, 8m, 8y, 8g: Spectroscopic element (prior stage spectroscopic element)
10, 10A, 10B, 10BX, 10BY: Pixel block
12, 12c, 12y, 12m, 12g: Color splitter (posterior stage spectroscopic element)
Cy: Cyan pixel
Mg: Magenta pixel
Ye: Yellow pixel
G: Green pixel
CF: Color filter
CFc: Color filter (cyan color filter)
CFm: Color filter (magenta color filter)
CFy: Color filter (yellow color filter)
CFg: Color filter (green color filter)
R Light: (Red light)
G Light: (Green light)
B Light: (Blue light)

What is claimed is:

1. An imaging element, comprising:
a pixel array that includes pixels that are arranged two-dimensionally and each of which has a photoelectric converter and a spectroscopic element that is arranged on a light incident side of the photoelectric converter and disperses light in a predetermined wavelength range,
wherein the pixels include cyan pixels that receive cyan light, magenta pixels that receive magenta light, and yellow pixels that receive yellow light.

2. The imaging element according to claim 1,
wherein the spectroscopic element of the cyan pixel is a first spectroscopic element that disperses red light toward the magenta pixel and the yellow pixel therearound,
the spectroscopic element of the magenta pixel is a second spectroscopic element that disperses green light toward the cyan pixel and the yellow pixel therearound, and
the spectroscopic element of the yellow pixel is a third spectroscopic element that disperses blue light toward the cyan pixel and the magenta pixel therearound.

3. The imaging element according to claim 1,
wherein the cyan pixel includes a cyan color filter that transmits cyan light,
the magenta pixel includes a magenta color filter that transmits magenta light, and
the yellow pixel includes a yellow color filter that transmits yellow light.

4. The imaging element according to claim 2,
wherein the pixel includes a green pixel that receives the green light, and
the pixel array includes pixel blocks each of which includes two pixels each in a vertical direction and a horizontal direction including the cyan pixel, the magenta pixel, the yellow pixel, and the green pixel and that are continuously arranged vertically and horizontally.

5. The imaging element according to claim 4,
wherein the spectroscopic element of the green pixel is a fourth spectroscopic element that disperses the red light toward the magenta pixel and the yellow pixel therearound and disperses the blue light toward the cyan pixel and the magenta pixel therearound.

6. The imaging element according to claim 5,
wherein the second spectroscopic element disperses the green light toward the cyan pixel, the yellow pixel, and the green pixel therearound.

7. The imaging element according to claim 5,
wherein the first spectroscopic element, the second spectroscopic element, the third spectroscopic element, and the fourth spectroscopic element execute the dispersion toward the photoelectric converter in the same pixel block.

8. The imaging element according to claim 7,
wherein the first spectroscopic element disperses the red light such that the red light is received by only either one of the magenta pixel and the yellow pixel within the same pixel block,
the second spectroscopic element disperses the green light such that the green light is received by only any one of the cyan pixel, the yellow pixel, and the green pixel within the same pixel block,
the third spectroscopic element disperses the blue light such that the blue light is received by only either one of the cyan pixel and the magenta pixel within the same pixel block, and
the fourth spectroscopic element disperses the red light such that the red light is received by only either one of the magenta pixel and the yellow pixel within the same pixel block and disperses the blue light such that the blue light is received by only either one of the cyan pixel and the magenta pixel within the same pixel block.

9. The imaging element according to claim 4,
wherein the green pixel includes a green color filter which transmits the green light.

10. The imaging element according to claim 1,
wherein the pixel has a rectangular shape as viewed from a light incident side, and
the pixel array includes the pixels arranged in a first direction and a second direction orthogonal to the first direction at equal intervals.

11. The imaging element according to claim 1,
wherein the pixel arranged in a portion other than an outer most peripheral portion of the pixel array is arranged so as to be surrounded by six of the pixels.

12. The imaging element according to claim 11,
wherein the six adjacent pixels of the cyan pixel are either one of the yellow pixels and the magenta pixels,
the six adjacent pixels of the yellow pixel are either one of the cyan pixels and the magenta pixels, and
the six adjacent pixels of the magenta pixel are either one of the cyan pixels and the yellow pixels.

13. The imaging element according to claim 11,
wherein the pixel has a hexagonal shape as viewed from a light incident side.

14. The imaging element according to claim 1,
wherein the spectroscopic element includes a plurality of types of microstructures having refractive indices different from one another.

15. The imaging element according to claim 1, comprising:
an on-chip microlens on a light incident side of the spectroscopic element.

16. An imaging element, comprising:
a pixel array that includes pixels arranged two-dimensionally and each of which has a photoelectric converter that includes a first-type photoelectric converter and a second-type photoelectric converter, a prior stage spectroscopic element that disperses light in a predetermined wavelength range of incident light toward another pixel, and a posterior stage spectroscopic element that is arranged between the prior stage spectroscopic element and the photoelectric converter, that disperses the light that has passed through the prior stage spectroscopic element to light in a first wavelength band and light in a second wavelength band, on a basis of a reference wavelength, that causes the first type photoelectric converter to receive the light in the first wavelength band, and that causes the second type photoelectric converter to receive the light in the second wavelength band.

17. The imaging element according to claim 16, comprising:
a plurality of the first type photoelectric converters and a plurality of the second type photoelectric converters.
